(19) United States
(12) Patent Application Publication
(10) Pub. No.: US 2025/0393327 A1
(43) Pub. Date: Dec. 25, 2025

(54) IMAGING DEVICE

(71) Applicant: SONY SEMICONDUCTOR SOLUTIONS CORPORATION, KANAGAWA (JP)

(72) Inventors: KOICHIRO ZAITSU, KANAGAWA (JP); AKIRA MATSUMOTO, KANAGAWA (JP)

(21) Appl. No.: 18/880,584

(22) PCT Filed: Jul. 7, 2023
(86) PCT No.: PCT/JP2023/025329

§ 371 Date: Jan. 2, 2025

(30) Foreign Application Priority Data
Jul. 22, 2022 (JP) 2022-117239

(51) Int. Cl. H10F 39/00

(52) U.S. Cl. CPC H10F 39/807; H10F 39/8027; H10F 39/8037

(57) ABSTRACT

Provided is an imaging device capable of suppressing generation of scattered light. The imaging device includes a semiconductor substrate having a first surface on which light is incident and a second surface located on an opposite side of the first surface, a plurality of pixels provided on the semiconductor substrate and configured to perform photoelectric conversion on the light, an inter-pixel isolation portion provided on the semiconductor substrate and isolating one pixel and another pixel adjacent to each other among the plurality of pixels, and a first protrusion provided on the semiconductor substrate and protruding from the inter-pixel isolation portion to an inside of the pixel. The first tip end portion of the first protrusion has a first portion located on the first surface side. The first portion has a material or structure that absorbs light as compared with the inter-pixel isolation portion.

### TECHNICAL FIELD

The present disclosure relates to an imaging device.

### BACKGROUND ART

In an imaging device, a method of detecting a phase difference using a pair of phase difference detection pixels is adopted as an autofocus function. As such an example, an imaging element disclosed in Patent Document 1 below can be mentioned.

### CITATION LIST

### Patent Document

Patent Document 1: WO 2021/193915 A

### SUMMARY OF THE INVENTION

### Problems to be Solved by the Invention

In the technique disclosed in Patent Document 1, pixels adjacent to each other are separated by a protrusion formed integrally with an element separation wall. When the light condensed by the lens is applied to the tip end portion of the protrusion, the light is scattered, and the light that has been scattered (hereinafter, also referred to as scattered light) may be incident on another pixel to cause color mixing.

The present disclosure has been made in view of such circumstances, and an object thereof is to provide an imaging device capable of suppressing generation of scattered light.

### Solutions to Problems

An imaging device according to one aspect of the present disclosure includes a semiconductor substrate having a first surface on which light is incident and a second surface located on an opposite side of the first surface, a plurality of pixels provided on the semiconductor substrate and configured to perform photoelectric conversion on the light, an inter-pixel isolation portion provided on the semiconductor substrate and isolating one pixel and another pixel adjacent to each other among the plurality of pixels, and a first protrusion provided on the semiconductor substrate and protruding from the inter-pixel isolation portion to an inside of the pixel. The first tip end portion of the first protrusion has a first portion located on the first surface side. The first portion has a material or structure that absorbs the light as compared with the inter-pixel isolation portion.

Accordingly, even in a case where light hits the first tip end portion of the first protrusion, reflection and scattering of light can be suppressed. Since the generation of scattered light can be suppressed, the occurrence of color mixing between pixels can be suppressed.

An imaging device according to another aspect of the present disclosure includes a semiconductor substrate having a first surface on which light is incident and a second surface located on an opposite side of the first surface, a plurality of pixels provided on the semiconductor substrate and configured to perform photoelectric conversion on the light, an inter-pixel isolation portion provided on the semiconductor substrate and isolating one pixel and another pixel adjacent to each other among the plurality of pixels, a first protrusion provided on the semiconductor substrate and protruding from the inter-pixel isolation portion to an inside of the pixel, and a second protrusion provided at a position facing the first protrusion in the semiconductor substrate and protruding from the inter-pixel isolation portion to an inside of the pixel. A gap exists between the first protrusion and the second protrusion. A central position of the gap is different between the first surface and the second surface in a direction in which the first protrusion and the second protrusion face each other.

According to this, on the first surface on which light is incident, a gap can be arranged in the central portion of the pixel, and the first protrusion and the second protrusion can be arranged outside the central portion of the pixel. Light can be prevented from being applied to the first protrusion and the second protrusion as much as possible, and reflection and scattering of light can be suppressed. Since the generation of scattered light can be suppressed, the occurrence of color mixing between pixels can be suppressed.

Furthermore, on the second surface located on the opposite side of the first surface, it is easy to arrange the gap functioning as the overflow path away from the transfer transistor arranged on the second surface side. Therefore, it is possible to suppress the potential of the overflow path from unintentionally varying due to the influence of the bias of the transfer transistor.

An imaging device according to still another aspect of the present disclosure includes a semiconductor substrate having a first surface on which light is incident and a second surface located on an opposite side of the first surface, a plurality of pixels provided on the semiconductor substrate and configured to perform photoelectric conversion on the light, an inter-pixel isolation portion provided on the semiconductor substrate and isolating one pixel and another pixel adjacent to each other among the plurality of pixels, a first protrusion provided on the semiconductor substrate and protruding from the inter-pixel isolation portion to an inside of the pixel, and a second protrusion provided at a position facing the first protrusion in the semiconductor substrate and protruding from the inter-pixel isolation portion to an inside of the pixel. The first protrusion and the second protrusion do not exist on the first surface but exist on the second surface. A gap exists between the first protrusion and the second protrusion.

Accordingly, on the first surface on which light is incident, the light does not hit the first protrusion and the second protrusion. Therefore, reflection and scattering of light can be suppressed, and generation of scattered light can be suppressed, so that color mixing between pixels can be suppressed.

### BRIEF DESCRIPTION OF DRAWINGS

FIG. 1 is a block diagram illustrating a configuration example of an imaging device according to a first embodiment of the present disclosure.

FIG. 2 is a plan view illustrating a configuration example of a pixel according to the first embodiment of the present disclosure.

FIG. 3 is a plan view illustrating a configuration example of a pixel according to the first embodiment of the present disclosure.

FIG. 4 is a cross-sectional view illustrating a configuration example of a pixel according to the first embodiment of the present disclosure.

FIG. 5 is a cross-sectional view illustrating a configuration example of a pixel according to the first embodiment of the present disclosure.

FIG. 6 is a plan view illustrating a configuration example of a pixel according to a comparative example of the present disclosure.

FIG. 7 is a cross-sectional view illustrating a configuration example of a pixel according to a comparative example of the present disclosure.

FIG. 8 is a plan view illustrating a configuration of a pixel according to a first modification of the first embodiment of the present disclosure.

FIG. 9 is a plan view illustrating a configuration of a pixel according to the first modification of the first embodiment of the present disclosure.

FIG. 10 is a cross-sectional view illustrating a configuration of a pixel according to the first modification of the first embodiment of the present disclosure.

FIG. 11 is a plan view illustrating a configuration of a pixel according to a second modification of the first embodiment of the present disclosure.

FIG. 12 is a cross-sectional view illustrating a configuration of a pixel according to the second modification of the first embodiment of the present disclosure.

FIG. 13 is a plan view illustrating a configuration of a pixel according to a third modification of the first embodiment of the present disclosure.

FIG. 14 is a plan view illustrating a configuration of a pixel according to a fourth modification of the first embodiment of the present disclosure.

FIG. 15 is a plan view illustrating a configuration of a pixel according to a fifth modification of the first embodiment of the present disclosure.

FIG. 16 is a plan view illustrating a configuration of a pixel according to a sixth modification of the first embodiment of the present disclosure.

FIG. 17 is a plan view illustrating a configuration of a pixel according to a seventh modification of the first embodiment of the present disclosure.

FIG. 18 is a cross-sectional view illustrating a configuration of a pixel according to an eighth modification of the first embodiment of the present disclosure.

FIG. 19 is a cross-sectional view illustrating a configuration of a pixel according to a ninth modification of the first embodiment of the present disclosure.

FIG. 20 is a cross-sectional view illustrating a configuration of a pixel according to a tenth modification of the first embodiment of the present disclosure.

FIG. 21 is a cross-sectional view illustrating a configuration of a pixel according to the tenth modification of the first embodiment of the present disclosure.

FIG. 22 is a cross-sectional view illustrating a light absorbing structure according to an eleventh modification of the first embodiment of the present disclosure.

FIG. 23 is a cross-sectional view illustrating a light absorbing structure according to a twelfth modification of the first embodiment of the present disclosure.

FIG. 24 is a cross-sectional view illustrating a manufacturing method (first method) of a pixel according to a second embodiment of the present disclosure in order of steps.

FIG. 25 is a cross-sectional view illustrating a manufacturing method (second method) of a pixel according to the second embodiment of the present disclosure in order of steps.

FIG. 26 is a cross-sectional view illustrating a manufacturing method (third method) of a pixel according to the second embodiment of the present disclosure in order of steps.

FIG. 27 is a cross-sectional view illustrating a manufacturing method (third method) of a pixel according to the second embodiment of the present disclosure in order of steps.

FIG. 28 is a cross-sectional view illustrating a manufacturing method (fourth method) of a pixel according to the second embodiment of the present disclosure in order of steps.

FIG. 29 is a plan view illustrating a configuration example of a pixel according to a third embodiment of the present disclosure.

FIG. 30 is a plan view illustrating a configuration example of a pixel according to the third embodiment of the present disclosure.

FIG. 31 is a cross-sectional view illustrating a configuration example of a pixel according to the third embodiment of the present disclosure.

FIG. 32A is a diagram illustrating a manufacturing method (first method) of a pixel according to the third embodiment of the present disclosure in order of steps.

FIG. 32B is a diagram illustrating a manufacturing method (first method) of a pixel according to the third embodiment of the present disclosure in order of steps.

FIG. 33A is a diagram illustrating a manufacturing method (first method) of a pixel according to the third embodiment of the present disclosure in order of steps.

FIG. 33B is a diagram illustrating a manufacturing method (first method) of a pixel according to the third embodiment of the present disclosure in order of steps.

FIG. 34A is a diagram illustrating a manufacturing method (second method) of a pixel according to the third embodiment of the present disclosure in order of steps.

FIG. 34B is a diagram illustrating a manufacturing method (second method) of a pixel according to the third embodiment of the present disclosure in order of steps.

FIG. 35A is a diagram illustrating a manufacturing method (second method) of a pixel according to the third embodiment of the present disclosure in order of steps.

FIG. 35B is a diagram illustrating a manufacturing method (second method) of a pixel according to the third embodiment of the present disclosure in order of steps.

FIG. 36A is a plan view illustrating a pixel according to a first modification of the third embodiment of the present disclosure.

FIG. 36B is a plan view illustrating a pixel according to a first modification of the third embodiment of the present disclosure.

FIG. 37A is a plan view illustrating a pixel according to a second modification of the third embodiment of the present disclosure.

FIG. 37B is a plan view illustrating a pixel according to a second modification of the third embodiment of the present disclosure.

FIG. 38A is a plan view illustrating a pixel 21N according to a third modification of the third embodiment of the present disclosure.

FIG. 38B is a plan view illustrating a pixel according to the third modification of the third embodiment of the present disclosure.

FIG. 39 is a plan view illustrating a pixel according to a fourth modification of the third embodiment of the present disclosure.

FIG. 40 is a plan view illustrating a pixel according to the fourth modification of the third embodiment of the present disclosure.

FIG. 41 is a cross-sectional view illustrating a configuration example of a pixel according to the fourth modification of the third embodiment of the present disclosure.

FIG. 42 is a cross-sectional view illustrating a manufacturing method (first method) of a pixel according to the fourth modification of the third embodiment of the present disclosure in order of steps.

FIG. 43 is a cross-sectional view illustrating a manufacturing method (first method) of a pixel according to the fourth modification of the third embodiment of the present disclosure in order of steps.

FIG. 44 is a cross-sectional view illustrating a manufacturing method (second method) of a pixel according to the fourth modification of the third embodiment of the present disclosure in order of steps.

FIG. 45 is a cross-sectional view illustrating a manufacturing method (second method) of a pixel according to the fourth modification of the third embodiment of the present disclosure in order of steps.

FIG. 46 is a plan view illustrating a configuration example of a pixel according to a fourth embodiment of the present disclosure.

FIG. 47 is a plan view illustrating a configuration example of a pixel according to the fourth embodiment of the present disclosure.

FIG. 48 is a cross-sectional view illustrating a configuration example of a pixel according to the fourth embodiment of the present disclosure.

FIG. 49A is a diagram illustrating a manufacturing method of a pixel according to the fourth embodiment of the present disclosure in order of steps.

FIG. 49B is a diagram illustrating a manufacturing method of a pixel according to the fourth embodiment of the present disclosure in order of steps.

FIG. 50A is a diagram illustrating a manufacturing method of a pixel according to the fourth embodiment of the present disclosure in order of steps.

FIG. 50B is a diagram illustrating a manufacturing method of a pixel according to the fourth embodiment of the present disclosure in order of steps.

FIG. 51 is a plan view illustrating a pixel according to a first modification of the fourth embodiment of the present disclosure.

FIG. 52 is a plan view illustrating a pixel according to a second modification of the fourth embodiment of the present disclosure.

### MODE FOR CARRYING OUT THE INVENTION

Hereinafter, embodiments of the present disclosure will be described with reference to the drawings. In the illustration of the drawings referred to in the following description, the same or similar portions are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description. Furthermore, it goes without saying that dimensional relationships and ratios are partly different between the drawings.

The definition of directions such as up and down in the following description is merely a definition for convenience of description, and does not limit the technical idea of the present disclosure. For example, it goes without saying that if a target is observed while being rotated by 90°, the upward and downward directions are converted into rightward and leftward, and if the target is observed while being rotated by 180°, the upward and downward are inverted.

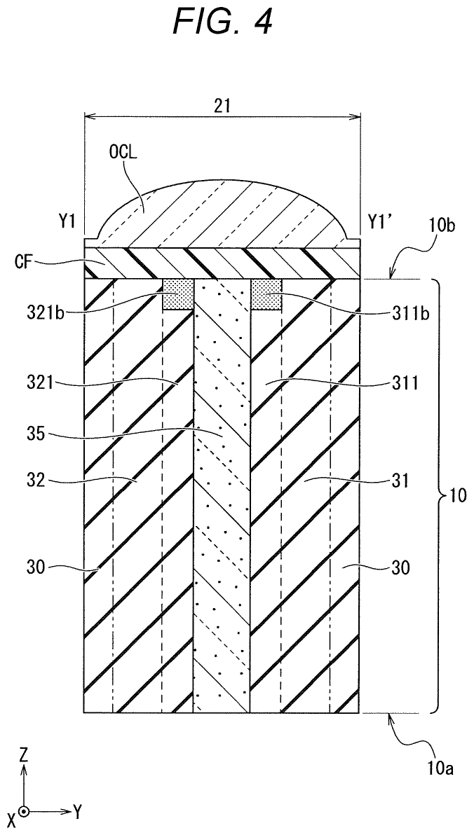

In the following description, there is a case where the direction is described using terms such as an X-axis direction, a Y-axis direction, and a Z-axis direction. For example, the X-axis direction and the Y-axis direction are directions parallel to a back surface 10b (see FIG. 4 described later) of a semiconductor substrate 10. The X-axis direction and the Y-axis direction are also referred to as horizontal directions. The Z-axis direction is a normal direction of the back surface 10b. The X-axis direction, the Y-axis direction, and the Z-axis direction are orthogonal to each other.

Furthermore, in the following description, “plan view” means, for example, viewing from a thickness direction (that is, the normal direction of the back surface 10b, and the Z-axis direction) of the semiconductor substrate 10.

### FIRST EMBODIMENT

### Overall Configuration Example of Imaging Device

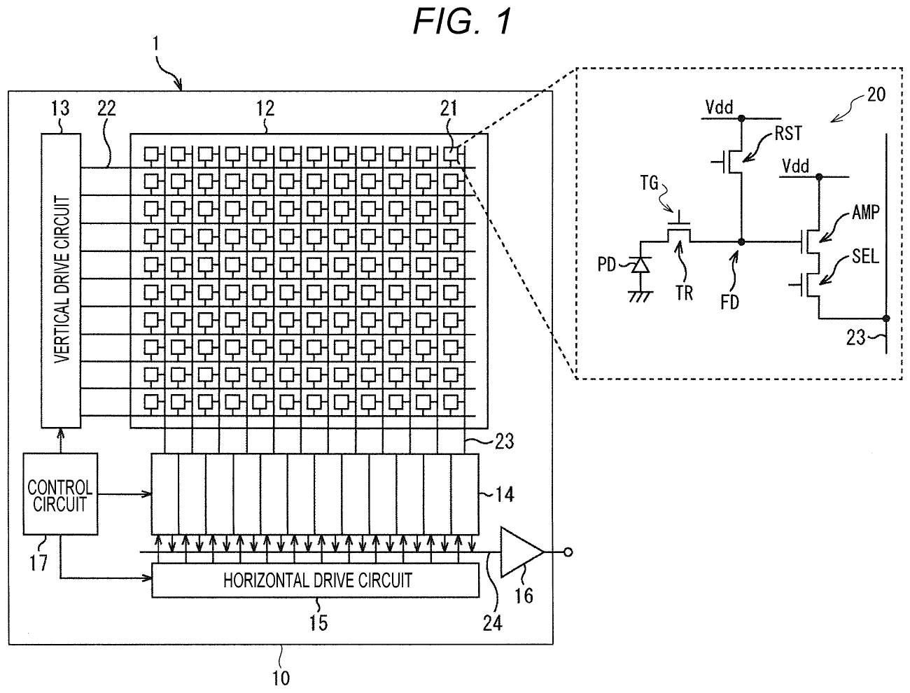

FIG. 1 is a block diagram illustrating a configuration example of an imaging device 1 according to a first embodiment of the present disclosure. As illustrated in FIG. 1, the imaging device 1 includes a semiconductor substrate 10, a pixel region 12 provided on the semiconductor substrate 10, a vertical drive circuit 13, a column signal processing circuit 14, a horizontal drive circuit 15, an output circuit 16, and a control circuit 17. The vertical drive circuit 13, the column signal processing circuit 14, the horizontal drive circuit 15, the output circuit 16, and the control circuit 17 may be provided on the semiconductor substrate 10, or may be provided on a second semiconductor substrate disposed on a front surface side of the (first) semiconductor substrate 10 via a multilayer wiring layer (all not illustrated) including a wiring layer and an interlayer insulating film.

The pixel region 12 is a light receiving region that receives light condensed by an optical system (for example, an on-chip lens OCL to be described later (see FIG. 4)), and includes a plurality of pixels 21. The plurality of pixels 21 is arranged in a matrix. The plurality of pixels 21 is connected to the vertical drive circuit 13 for every row via horizontal signal lines 22, and is connected to the column signal processing circuit 14 for every column via vertical signal lines 23. The plurality of pixels 21 outputs pixel signals at levels corresponding to an amount of light respectively received. An image of a subject is constructed from these pixel signals.

The vertical drive circuit 13 sequentially supplies drive signals for driving (such as transferring, selecting, and resetting) the respective pixels 21 for every row of the plurality of pixels 21 to the pixels 21 via the horizontal signal lines 22. By performing correlated double sampling (CDS) processing on the pixel signals output from the plurality of pixels 21 via the vertical signal lines 23, the column signal processing circuit 14 performs analog-to-signal (AD) conversion on the pixel signals and removes reset noise.

The horizontal drive circuit 15 sequentially supplies the column signal processing circuit 14 with drive signals for causing the column signal processing circuit 14 to output the pixel signals to a data output signal line 24 for every column of the plurality of pixels 21. The output circuit 16 amplifies the pixel signals supplied from the column signal processing circuit 14 via the data output signal line 24 at a timing according to the drive signals of the horizontal drive circuit 15, and outputs the amplified pixel signals to a signal processing circuit of a subsequent stage. The control circuit 17 controls driving of respective blocks inside the imaging device 1. For example, the control circuit 17 generates a clock signal according to a drive cycle of each block and supplies the clock signals to the respective blocks.

The pixel 21 includes a photodiode PD, a transfer transistor TR, a floating diffusion FD, an amplification transistor AMP, a selection transistor SEL, and a reset transistor RST. The transfer transistor TR, the floating diffusion FD, the amplification transistor AMP, the selection transistor SEL, and the reset transistor RST constitute a read circuit 20 that reads a charge (pixel signal) photoelectrically converted by the photodiode PD.

The photodiode PD is a photoelectric conversion unit that converts incident visible light into a charge by photoelectric conversion and stores the charge, and has an anode terminal grounded and a cathode terminal connected to the transfer transistor TR. A transfer signal is supplied from the vertical drive circuit 13 to a gate electrode TG of the transfer transistor TR. The transfer transistor TR is driven in accordance with the transfer signal supplied to the gate electrode TG. Hereinafter, the gate electrode TG is also referred to as a transfer gate. When the transfer transistor TR is turned on, the charge accumulated in the photodiode PD is transferred to the floating diffusion FD. The floating diffusion FD is a floating diffusion region having a predetermined storage capacitance connected to the gate electrode of the amplification transistor AMP, and temporarily stores the charge transferred from the photodiode PD.

The amplification transistor AMP outputs the pixel signal of a level (that is, a potential of the floating diffusion FD) corresponding to the charge accumulated in the floating diffusion FD to the vertical signal line 23 via the selection transistor SEL. That is, with the configuration in which the floating diffusion FD is connected to the gate electrode of the amplification transistor AMP, the floating diffusion FD and the amplification transistor AMP function as a conversion unit that amplifies the charge generated in the photodiode PD and converts the charge into the pixel signal at the level corresponding to the charge.

The selection transistor SEL is driven in accordance with a select signal supplied from the vertical drive circuit 13, and when the selection transistor SEL is turned on, the pixel signal output from the amplification transistor AMP can be output to the vertical signal line 23. The reset transistor RST is driven in accordance with a reset signal supplied from the vertical drive circuit 13, and when the reset transistor RST is turned on, the charge stored in the floating diffusion FD is discharged to a power line Vdd, and the floating diffusion FD is reset.

### Configuration Example of Pixel

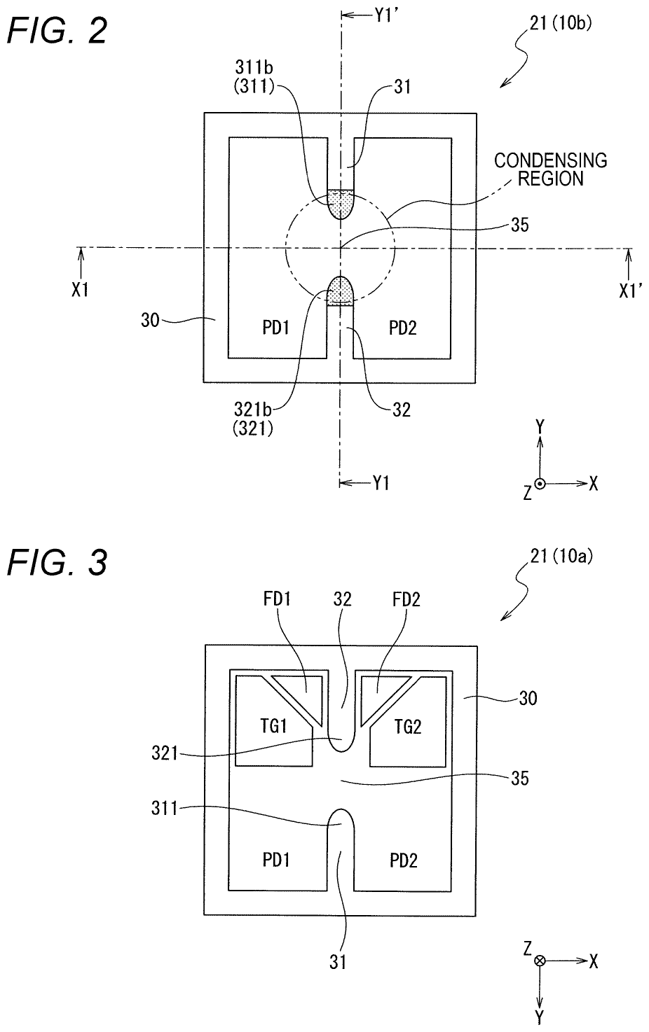

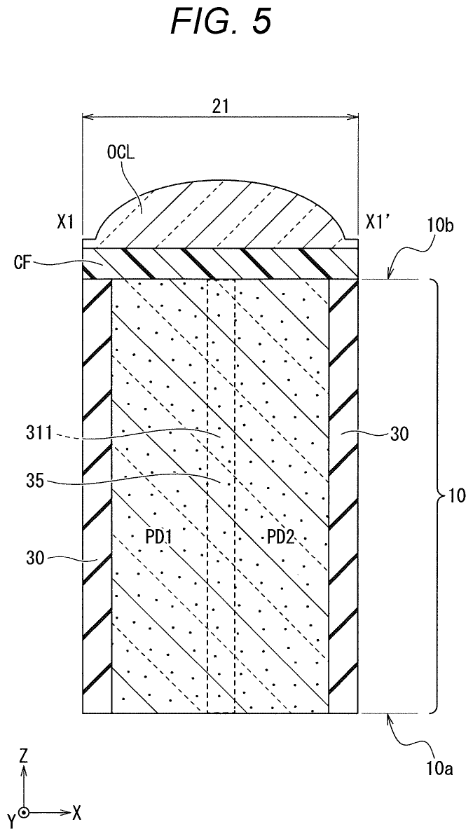

FIGS. 2 and 3 are plan views illustrating configuration examples of the pixel 21 according to the first embodiment of the present disclosure. FIG. 2 is a diagram of the pixel 21 as viewed from the back surface 10b side of the semiconductor substrate 10, and FIG. 3 is a diagram of the pixel 21 as viewed from the front surface 10a side of the semiconductor substrate. FIGS. 4 and 5 are cross-sectional views illustrating configuration examples of the pixel 21 according to the first embodiment of the present disclosure. FIG. 4 corresponds to a cross section of the plan view of FIG. 2 taken along line Y1-Y1′. FIG. 5 corresponds to a cross section of the plan view of FIG. 2 taken along line X1-X1′. Note that, in FIG. 2, illustration of the on-chip lens OCL and the color filter CF is omitted in order to illustrate an inter-pixel isolation portion 30, a first protrusion 31, and a second protrusion 32.

The imaging device 1 is, for example, a back-illumination CMOS image sensor. As illustrated in FIGS. 2 to 5, the semiconductor substrate 10 included in the imaging device 1 has a back surface 10b (an example of a “first surface” of the present disclosure) on which light is incident and a front surface 10a (an example of a “second surface” of the present disclosure) located on an opposite side of the back surface 10b. The back surface 10b is a light-receiving surface.

The imaging device 1 includes a plurality of pixels 21 that is provided on the semiconductor substrate 10 and performs photoelectric conversion on incident light, an inter-pixel isolation portion 30 that is provided on the semiconductor substrate 10 and isolates one pixel 21 and the other pixel 21 adjacent to each other among the plurality of pixels 21, and a first protrusion 31 and a second protrusion 32 that are provided on the semiconductor substrate 10 and protrude from the inter-pixel isolation portion 30 to the inside of the pixel 21.

The inter-pixel isolation portion 30, the first protrusion 31, and the second protrusion 32 are provided so as to penetrate the semiconductor substrate 10 from the back surface 10b to the front surface 10a of the semiconductor substrate 10.

Furthermore, the imaging device 1 includes a color filter CF provided on the back surface 10b side of the semiconductor substrate 10 and an on-chip lens (an example of a “lens body” of the present disclosure) OCL provided on the back surface 10b side via the color filter CF.

Hereinafter, the multilayer structure of the pixel 21 will be described. In the description, the multilayer structure will be described in order from the upper side (back surface 10b side) to the lower side in FIGS. 4 and 5.

One on-chip lens OCL is provided for each of the plurality of pixels 21. The on-chip lens OCL condenses light on the pixel 21 located below the on-chip lens OCL. The on-chip lens OCL can include, for example, a silicon nitride film (SiN), or a resin material such as a styrene resin, an acrylic resin, a styrene-acrylic copolymer resin, or a siloxane resin.

The color filter CF is any of a color filter that transmits a red wavelength component, a color filter that transmits a green wavelength component, and a color filter that transmits a blue wavelength component. The color filter CF can include, for example, a material in which a pigment or a dye is dispersed in a transparent binder such as silicone.

The semiconductor substrate 10 is, for example, a P-type silicon (Si) substrate. For example, a first photodiode PD1 and a second photodiode PD2 including an N-type impurity diffusion layer are provided in a P-type silicon substrate. The first photodiode PD1 is an example of a “first photoelectric conversion unit” of the present disclosure, and the second photodiode PD2 is an example of a “second photoelectric conversion unit” of the present disclosure. The first photodiode PD1 and the second photodiode PD2 photoelectrically convert light having a red wavelength component, a green wavelength component, or a blue wavelength component incident through the color filter CF to generate charges.

The charge generated by the first photodiode PD1 is transferred to a floating diffusion FD1 via a transfer gate TG1 of a transfer transistor TR1 provided on the front surface 10a side of the semiconductor substrate 10. Similarly, the charge generated by the second photodiode PD2 is transferred to a floating diffusion FD2 via a transfer gate TG2 of a transfer transistor TR2 provided on the front surface 10a side of the semiconductor substrate 10.

Note that each of the first photodiode PD1 and the second photodiode PD2 corresponds to the photodiode PD illustrated in FIG. 1. Each of the transfer transistors TR1 and TR2 corresponds to the transfer transistor TR illustrated in FIG. 1. Each of the transfer gates TG1 and TG2 corresponds to the transfer gate TG illustrated in FIG. 1. Each of the floating diffusions FD1 and FD2 corresponds to the floating diffusion FD illustrated in FIG. 1.

The first photodiode PD1 and the second photodiode PD2 function as a pair of phase difference detection pixels at the time of phase difference detection. That is, in each of the plurality of pixels 21, the phase difference can be detected by detecting a difference (alternatively, the ratio of the pixel signals) between pixel signals based on charges generated by the pair of first photodiodes PD1 and second photodiodes PD2. This phase difference is detected as a difference signal by the output circuit 16 illustrated in FIG. 1, for example, a defocus amount is calculated on the basis of the detected phase difference, and an image forming lens (not illustrated) is adjusted (moved), whereby autofocus can be realized.

The inter-pixel isolation portion 30 surrounds the first photodiode PD1 and the second photodiode PD2 and physically isolates the adjacent pixels 21. The inter-pixel isolation portion 30 includes a trench (not illustrated) provided so as to penetrate the semiconductor substrate 10 along a thickness direction (for example, the Z-axis direction) thereof, and an embedded material embedded in the trench. Examples of the embedded material used for the inter-pixel isolation portion 30 include an oxide film or a metal film of a silicon oxide film (SiO), a silicon nitride film (SiN), amorphous silicon (a-Si), polycrystalline silicon (poly-Si), a titanium oxide film (TiO), aluminum (Al), tungsten (W), or the like.

As illustrated in FIGS. 2 and 3, the first protrusion 31 protrudes from the inter-pixel isolation portion 30 to the inside of the pixel 21. The second protrusion 32 is provided at a position facing the first protrusion 31, and protrudes from the inter-pixel isolation portion 30 to the inside of the pixel 21. In plan view from the back surface 10b side of the semiconductor substrate 10, the first protrusion 31 and the second protrusion 32 are disposed between the first photodiode PD1 and the second photodiode PD2. The first protrusion 31 and the second protrusion 32 separate the first photodiode PD1 and the second photodiode PD2 from each other.

The first protrusion 31 and the second protrusion 32 include a trench (not illustrated) provided so as to penetrate the semiconductor substrate 10 along a thickness direction (for example, the Z-axis direction) thereof, and an embedded material embedded in the trench. Examples of the embedded material used for the first protrusion 31 and the second protrusion 32 include an oxide film or a metal film of a silicon oxide film, a silicon nitride film, amorphous silicon, polycrystalline silicon, a titanium oxide film, aluminum, tungsten, or the like.

Lengths of the first protrusion 31 and the second protrusion 32 in the protruding direction from the inter-pixel isolation portion 30 are the same (or substantially the same). In FIGS. 2 and 3, the length of the first protrusion 31 and the second protrusion 32 in the protruding direction corresponds to the length in the Y-axis direction. Furthermore, the line widths of the first protrusion 31 and the second protrusion 32 are the same (or substantially the same). The line width is a length in the width direction. In FIGS. 2 and 3, the line widths of the first protrusion 31 and the second protrusion 32 correspond to the lengths in the X-axis direction.

A gap (slit) 35 exists between a first tip end portion 311 of the first protrusion 31 and a second tip end portion 321 of the second protrusion 32. The gap 35 electrically isolates the pair of first photodiode PD1 and second photodiode PD2 at the time of phase difference detection, and functions as an overflow path at the time of normal imaging. When one of the first photodiode PD1 and the second photodiode PD2 is about to be saturated with charge at the time of normal imaging, the charge can be transferred from one of the first photodiode PD1 and the second photodiode PD2 to the other via the overflow path, and saturation of the charge can be avoided. Therefore, the linearity of the pixel signal output from the pixel 21 can be secured, and deterioration of the captured image can be prevented.

On the back surface 10b of the semiconductor substrate 10, which is the light-receiving surface, the gap 35 is provided at the central portion of the pixel 21. The central portion of the pixel 21 exists, for example, in a condensing region where the on-chip lens OCL condenses light. Furthermore, the first protrusion 31 and the second protrusion 32 exist outside the central portion of the pixel 21. With this structure, the light incident on the back surface 10b of the semiconductor substrate 10 can be transmitted through the gap 35 and the like existing in the central portion of the pixel 21 and incident on the first photodiode PD1 and the second photodiode PD2.

However, the first tip end portion 311 of the first protrusion 31 and the second tip end portion 321 of the second protrusion 32 may be disposed so as to cover the outer edge or the like of the condensing region instead of being completely removed from the condensing region. Due to optical path design and manufacturing variations, there is a case where it is difficult to arrange (that is, light is not completely applied) all of the first tip end portion 311 and the second tip end portion 321 so as not to overlap the condensing region. Furthermore, in particular, since long-wavelength light is likely to be diffracted, in a case where long-wavelength light is to be subjected to photoelectric conversion, the light tends to easily hit the first tip end portion 311 and the second tip end portion 321.

Therefore, in the pixel 21 according to the first embodiment, each of a back surface side portion 311b (an example of the “first portion” of the present disclosure), which is the first tip end portion 311 of the first protrusion 31 and is located on the back surface 10b side of the semiconductor substrate 10, and a back surface side portion 321b (an example of the “first portion” of the present disclosure), which is the second tip end portion 321 of the second protrusion 32 and is located on the back surface 10b side of the semiconductor substrate 10, contains a material (hereinafter, also referred to as a light absorbing material) that absorbs light as compared with the inter-pixel isolation portion 30. Therefore, even in a case where light hits the first tip end portion 311 and the second tip end portion 321, reflection and scattering of light can be suppressed as compared with the comparative example described later. The occurrence of color mixing between the pixels 21 due to reflection and scattering of light can be suppressed.

Examples of the light absorbing material used for the back surface side portions 311b and 321b include a high refractive index material (for example, a titanium oxide film (TiO) or the like), a Si-based material (for example, polycrystalline silicon (poly-Si), amorphous silicon (a-Si), silicon (Si (Epi)) formed by an epitaxial growth method, or the like), a black material, and a light absorbing material such as tungsten (W).

For example, in a case where Sio is used as the embedded material of the inter-pixel isolation portion 30, a Si-based material having a refractive index higher than that of Sio is used for the back surface side portions 311b and 321b. Furthermore, in a case where a Si-based material is used as the embedded material of the inter-pixel isolation portion 30, a high refractive index material having a refractive index higher than that of the Si-based material is used for the back surface side portions 311b and 321b.

The lengths of the back surface side portions 311b and 321b in the protruding direction are the same (or substantially the same). The line widths of the back surface side portions 311b and 321b are also the same (or substantially the same). Materials or structures constituting the back surface side portions 311b and 321b are also the same (or substantially the same).

### Comparative Examples

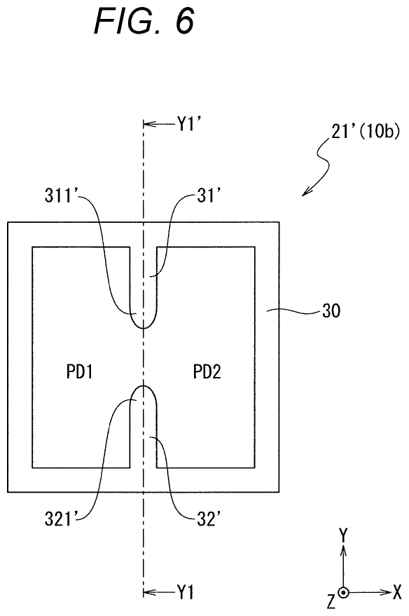

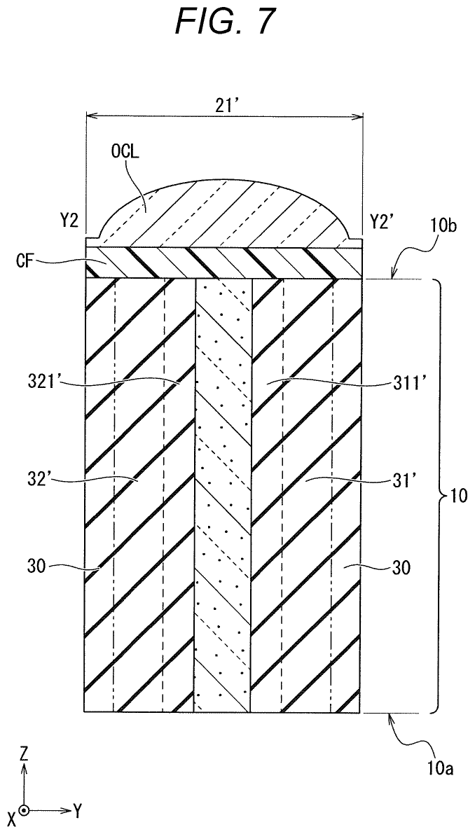

FIG. 6 is a plan view illustrating a configuration example of a pixel 21′ according to a comparative example of the present disclosure. FIG. 7 is a cross-sectional view illustrating a configuration example of the pixel 21′ according to the comparative example of the present disclosure. FIG. 7 corresponds to a cross section of the plan view of FIG. 6 taken along line Y2-Y2′. As illustrated in FIGS. 6 and 7, the pixel 21 according to the comparative example includes a first protrusion 31′ and a second protrusion 32′ protruding from an inter-pixel isolation portion 30′ to the inside of the pixel.

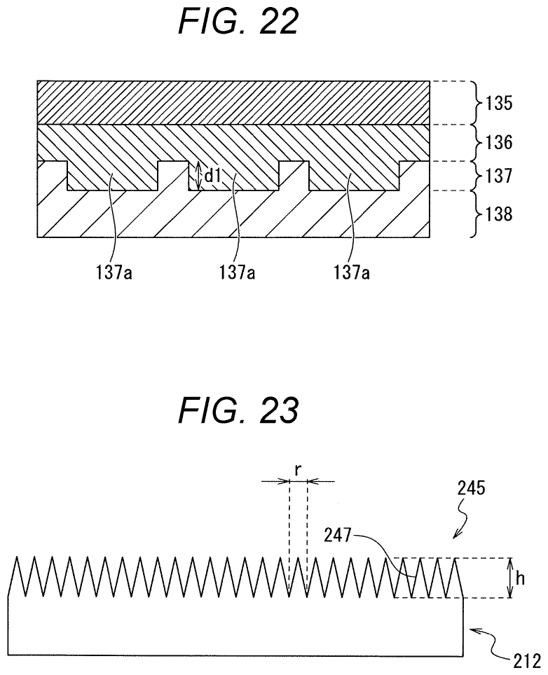

Each of the first protrusion 31′ and the second protrusion 32′ contains the same material as that of the inter-pixel isolation portion 30. A material that absorbs light (light absorbing material) is not used for the first tip end portion 311′ of the first protrusion 31′ and the second tip end portion 321′ of the second protrusion 32′ as compared with the inter-pixel isolation portion 30. Furthermore, the first tip end portion 311′ and the second tip end portion 321′ are not provided with a light absorbing structure as illustrated in eleventh and twelfth modifications (FIGS. 22 and 23) to be described later. Therefore, in the comparative example, when the first tip end portion 311′ and the second tip end portion 321′ are irradiated with light, scattering is likely to occur, and color mixing may occur due to the scattered light.

### Effect of First Embodiment

As described above, the imaging device 1 according to the first embodiment of the present disclosure includes the semiconductor substrate 10 having the back surface 10b on which light is incident and the front surface 10a located on the opposite side of the back surface 10b, the plurality of pixels 21 provided on the semiconductor substrate 10 and performing photoelectric conversion on light, the inter-pixel isolation portion 30 provided on the semiconductor substrate 10 and isolating one pixel 21 and the other pixel 21 adjacent to each other among the plurality of pixels 21, and the first protrusion 31 provided on the semiconductor substrate 10 and protruding from the inter-pixel isolation portion 30 to the inside of the pixel 21. The first tip end portion 311 of the first protrusion 31 has a back surface side portion 311b located on the back surface 10b side. The back surface side portion 311b has a material (for example, a high refractive index material, a light absorbing material such as a black material, or a light absorbing material such as tungsten (W)) that absorbs light as compared with the inter-pixel isolation portion 30.

Accordingly, even in a case where light hits the first tip end portion 311 of the first protrusion 31, reflection and scattering of light can be suppressed. Since it is possible to suppress generation of scattered light by light hitting the first tip end portion 311, it is possible to suppress occurrence of color mixing between the pixels 21.

Furthermore, the imaging device 1 further includes a second protrusion 32 that is provided at a position facing the first protrusion 31 on the semiconductor substrate 10 and protrudes from the inter-pixel isolation portion 30 to the inside of the pixel 21. A gap 35 exists between the first protrusion 31 and the second protrusion 32. The second tip end portion 321 of the second protrusion 32 has a back surface side portion 321b. Similarly to the back surface side portion 311b of the first tip end portion 311, the back surface side portion 321b of the second tip end portion 321 also has a material that absorbs light as compared with the inter-pixel isolation portion 30.

Accordingly, even in a case where light hits the second tip end portion 321 of the second protrusion 32, reflection and scattering of light can be suppressed. Since it is possible to suppress generation of scattered light by light hitting the second tip end portion 321, it is possible to further suppress occurrence of color mixing between the pixels 21.

### Modifications

Next, modifications of the first embodiment of the present disclosure will be described.

### (1) First Modification

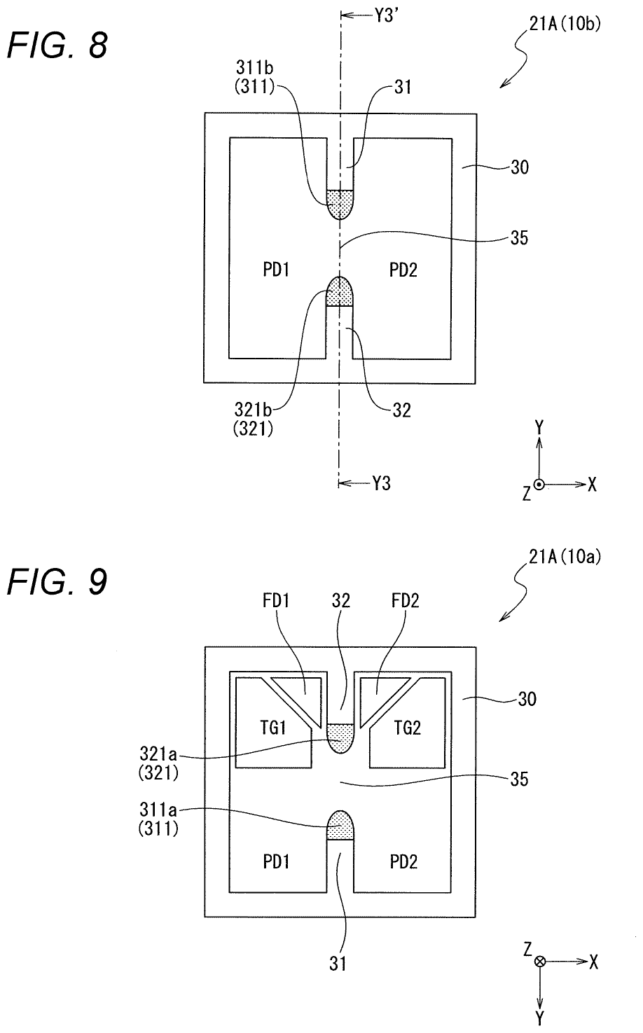

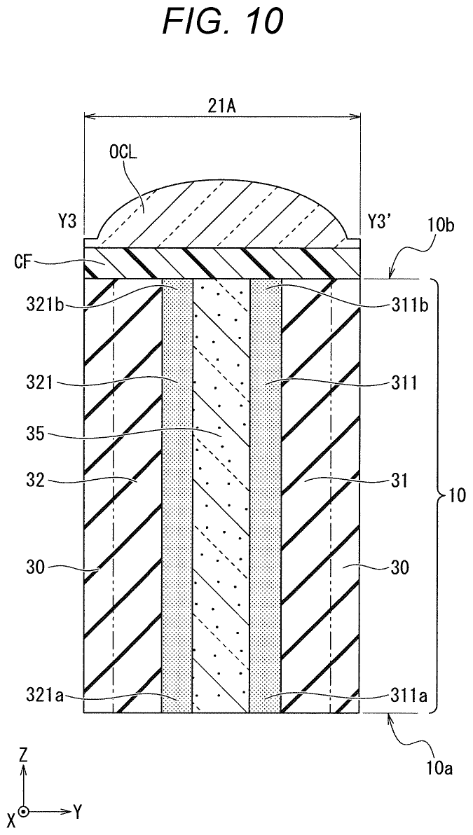

FIGS. 8 and 9 are plan views illustrating the configuration of a pixel 21A according to a first modification of the first embodiment of the present disclosure. FIG. 10 is a cross-sectional view illustrating the configuration of the pixel 21A according to the first modification of the first embodiment of the present disclosure. FIG. 8 is a diagram of the pixel 21A as viewed from the back surface 10b side of the semiconductor substrate 10, and FIG. 9 is a diagram of the pixel 21A as viewed from the front surface 10a side of the semiconductor substrate. FIG. 10 corresponds to a cross section of the plan view of FIG. 8 taken along line Y3-Y3′.

As illustrated in FIGS. 8 to 10, in the pixel 21A according to the first modification of the first embodiment, the entire first tip end portion 311 of the first protrusion 31 and the entire second tip end portion 321 of the second protrusion 32 contain a material (light absorbing material) that absorbs light as compared with the inter-pixel isolation portion 30.

That is, in the first tip end portion 311 of the first protrusion 31, a region from the back surface side portion 311b located on the back surface 10b side of the semiconductor substrate 10 to the front surface side portion 311a (an example of the “second portion” of the present disclosure) located on the front surface 10a side of the semiconductor substrate 10 contain the light absorbing material. Similarly, in the second tip end portion 321 of the second protrusion 32, a region from the back surface side portion 321b located on the back surface 10b side of the semiconductor substrate 10 to the front surface side portion 321a (an example of a “second portion” in the present disclosure) located on the front surface 10a side of the semiconductor substrate 10 contain a light absorbing material.

Also in the pixel 21A, since the generation of scattered light can be suppressed, the occurrence of color mixing can be suppressed.

### (2) Second Modification

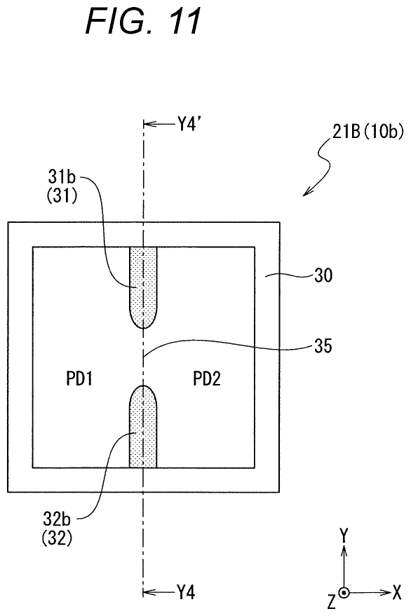

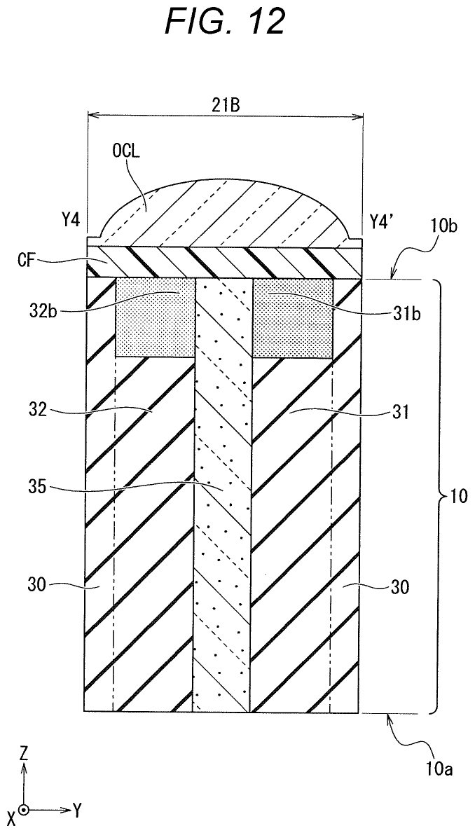

FIG. 11 is a plan view illustrating a configuration of a pixel 21B according to a second modification of the first embodiment of the present disclosure. FIG. 12 is a cross-sectional view illustrating a configuration of the pixel 21B according to the second modification of the first embodiment of the present disclosure. FIG. 11 is a diagram of the pixel 21B as viewed from the back surface 10b side of the semiconductor substrate 10. FIG. 12 corresponds to a cross section of the plan view of FIG. 11 taken along line Y4-Y4′.

As illustrated in FIGS. 11 and 12, in the pixel 21B according to the second modification of the first embodiment, the back surface side portion 31b of the first protrusion 31 contains a material (light absorbing material) that absorbs light as compared with the inter-pixel isolation portion 30, unlike other portions of the first protrusion 31. The back surface side portion 31b is a portion located on the back surface 10b side of the semiconductor substrate 10 in the first protrusion 31, and includes the back surface side portion 311b (see FIG. 2) of the tip end portion of the first protrusion 31. That is, in the pixel 21B, on the back surface 10b, the entire first protrusion 31 contains a material (light absorbing material) that absorbs light as compared with the inter-pixel isolation portion 30.

Similarly, a back surface side portion 32b of the second protrusion 32 contains a light absorbing material unlike other portions of the second protrusion 32. The back surface side portion 32b is a portion located on the back surface 10b side of the semiconductor substrate 10 in the second protrusion 32, and includes the back surface side portion 321b (see FIG. 2) of the tip end portion of the second protrusion 32.

That is, in the pixel 21B, on the back surface 10b, the entire second protrusion 32 contains a material (light absorbing material) that absorbs light as compared with the inter-pixel isolation portion 30.

Also in the pixel 21B, since the generation of scattered light can be suppressed, the occurrence of color mixing can be suppressed.

### (3) Third Modification

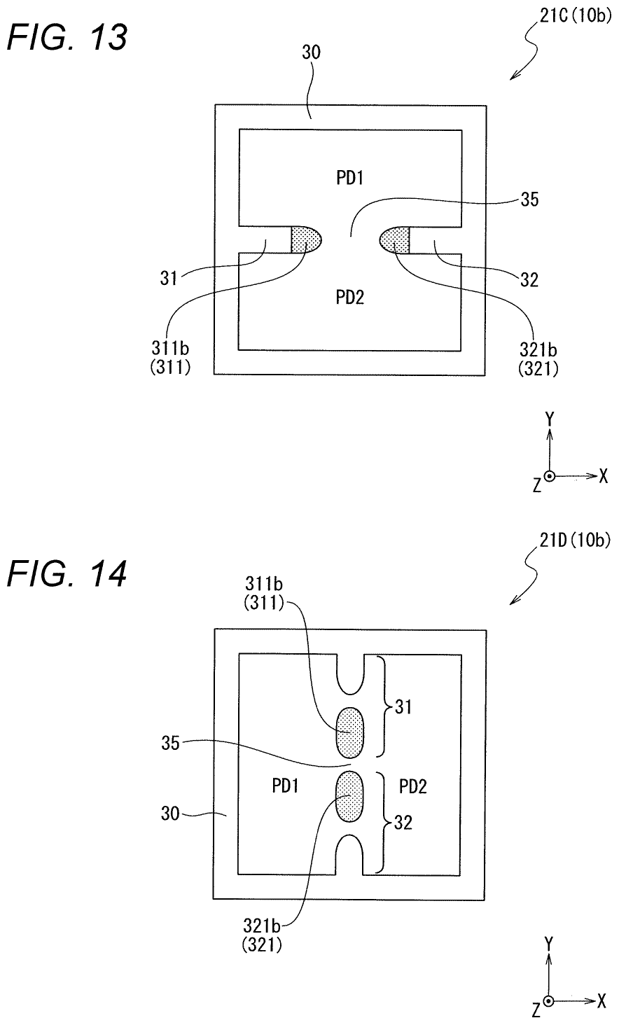

FIG. 13 is a plan view illustrating a configuration of a pixel 21C according to a third modification of the first embodiment of the present disclosure. FIG. 13 is a diagram of the pixel 21C as viewed from the back surface 10b side of the semiconductor substrate 10. As illustrated in FIG. 13, in the pixel 21C according to the third modification of the first embodiment, the first photodiode PD1 and the second photodiode PD2 are arranged side by side in the Y-axis direction (vertical direction in plan view) instead of the X-axis direction (horizontal direction in plan view). Then, the first protrusion 31 and the second protrusion 32 protrude in the Y-axis direction so as to separate the first photodiode PD1 and the second photodiode PD2 from each other.

Also in the pixel 21C, since the generation of scattered light can be suppressed, the occurrence of color mixing can be suppressed.

### (4) Fourth Modification

FIG. 14 is a plan view illustrating a configuration of a pixel 21D according to a fourth modification of the first embodiment of the present disclosure. FIG. 14 is a diagram of the pixel 21D as viewed from the back surface 10b side of the semiconductor substrate 10. As illustrated in FIG. 14, in the pixel 21D according to the fourth modification of the first embodiment, the first protrusion 31 and the second protrusion 32 are arranged in a dot shape (that is, island-like) so as to separate the first photodiode PD1 and the second photodiode PD2 from each other.

In the first protrusions 31 arranged in a dot shape, a portion closest to the central portion of the pixel 21D is the first tip end portion 311. The back surface side portion 311b of the first tip end portion 311 contains a material (light absorbing material) that absorbs light as compared with the inter-pixel isolation portion 30. Similarly, in the second protrusion 32 arranged in a dot shape, a portion closest to the central portion of the pixel 21D is the second tip end portion 321. The back surface side portion 321b of the second tip end portion 321 contains a light absorbing material.

Also in the pixel 21D, since the generation of scattered light can be suppressed, the occurrence of color mixing can be suppressed.

### (5) Fifth Modification

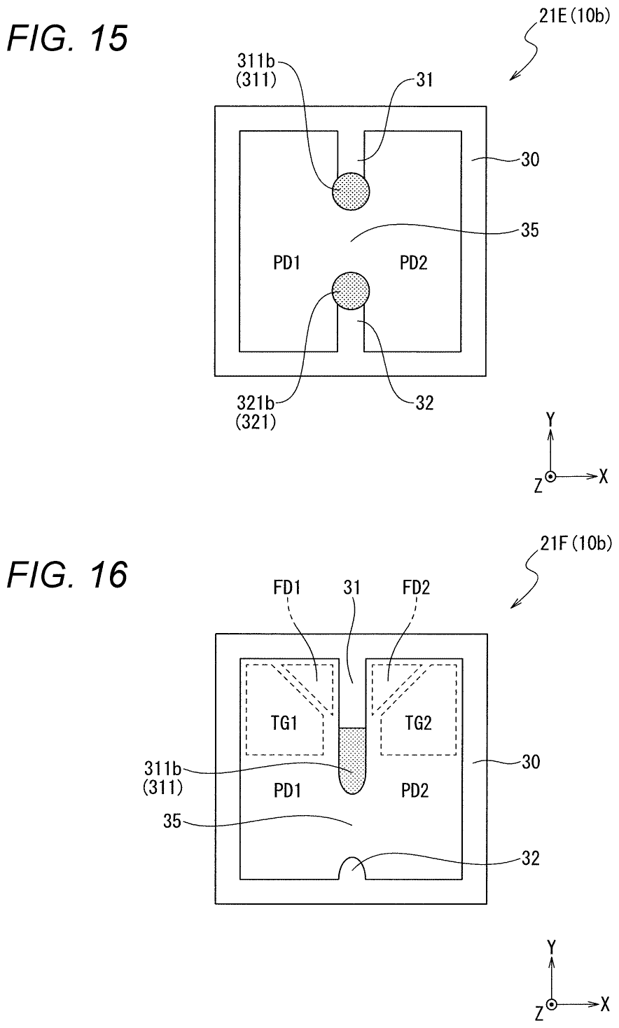

FIG. 15 is a plan view illustrating a configuration of a pixel 21E according to a fifth modification of the first embodiment of the present disclosure. FIG. 15 is a diagram of the pixel 21E as viewed from the back surface 10b side of the semiconductor substrate 10. As illustrated in FIG. 15, in the pixel 21E according to the fifth modification of the first embodiment, the first tip end portion 311 of the first protrusion 31 has a larger line width than other portions of the first protrusion 31. For example, the shape of the first tip end portion 311 in plan view is circular (or substantially circular), and the diameter thereof is larger than the line widths of the other portions of the first protrusion 31. The back surface side portion 311b of the first tip end portion 311 contains a light absorbing material.

Similarly, the line width of the second tip end portion 321 of the second protrusion 32 is larger than those of other portions of the second protrusion 32. For example, the shape of the second tip end portion 321 in plan view is circular (or substantially circular), and the diameter thereof is larger than the line widths of the other portions of the second protrusion 32. The back surface side portion 321b of the second tip end portion 321 having a large diameter contains a light absorbing material.

Also in the pixel 21E, since the generation of scattered light can be suppressed, the occurrence of color mixing can be suppressed.

### (6) Sixth Modification

In the embodiment of the present disclosure, the shapes and sizes of the first protrusion 31 and the second protrusion 32 may not be the same.

FIG. 16 is a plan view illustrating a configuration of a pixel 21F according to a sixth modification of the first embodiment of the present disclosure. FIG. 16 is a diagram of the pixel 21F as viewed from the back surface 10b side of the semiconductor substrate 10. As illustrated in FIG. 16, in the pixel 21F according to the sixth modification of the first embodiment, for example, due to pixel design convenience, a gap 35 functioning as an overflow path is formed at a position lower than the central portion of the pixel 21F in plan view. For example, the central portion of the pixel 21F is an optical center. In the pixel 21F, the first protrusion 31 is longer than the second protrusion 32 in the protruding direction, and the first tip end portion 311 of the first protrusion 31 is closer to the central portion of the pixel 21F than the second protrusion 32. In the pixel 21F, the back surface side portion 311b of the first tip end portion 311 close to the central portion of the pixel 21F contains a light absorbing material.

Also in the pixel 21F, since the generation of scattered light can be suppressed, the occurrence of color mixing can be suppressed.

### (7) Seventh Modification

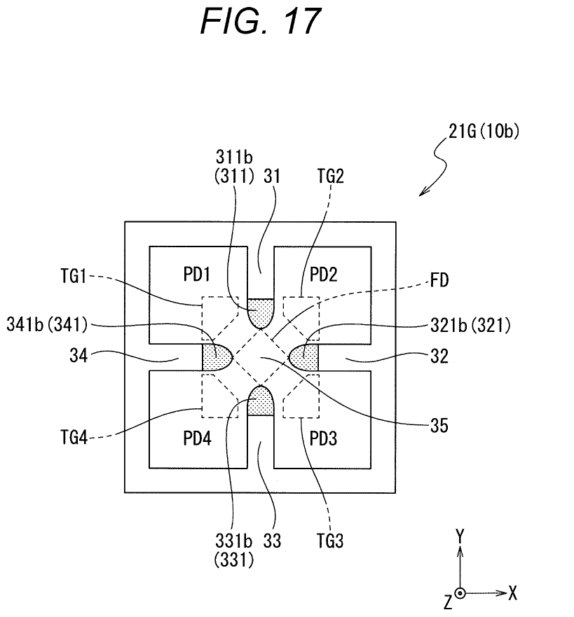

In the first embodiment of the present disclosure, the photodiodes in one pixel surrounded by the inter-pixel isolation portion 30 are not limited to two of the first photodiode PD1 and the second photodiode PD2. FIG. 17 is a plan view illustrating a configuration of a pixel 21G according to a seventh modification of the first embodiment of the present disclosure. FIG. 17 is a diagram of the pixel 21G as viewed from the back surface 10b side of the semiconductor substrate 10.

As illustrated in FIG. 17, the pixel 21G according to the seventh modification of the first embodiment may have a configuration in which a total of four photodiodes (first photodiode PD1, second photodiode PD2, third photodiode PD3, and fourth photodiode PD4), two of which are arranged in each of the horizontal direction (for example, the X-axis direction) and the vertical direction (for example, the Y-axis direction) in plan view, share one floating diffusion FD arranged in the central portion of the pixel 21G. This configuration may be referred to as a 2×2 type from the number and arrangement of photodiodes surrounded by the inter-pixel isolation portion 30.

As illustrated in FIG. 17, the first photodiode PD1 and the second photodiode PD2 are separated from each other by the first protrusion 31 protruding from the inter-pixel isolation portion 30 to the inside of the pixel 21G. The first tip end portion 311 of the first protrusion 31 is located at a position close to the central portion (optical center) of the pixel 21, and the back surface side portion 311b contains a light absorbing material.

Similarly, the second photodiode PD2 and the third photodiode PD3 are separated from each other by the second protrusion 32 protruding from the inter-pixel isolation portion 30 to the inside of the pixel 21G. The second tip end portion 321 of the second protrusion 32 is located at a position close to the optical center, and the back surface side portion 321b contains a light absorbing material.

The second photodiode PD2 and the third photodiode PD3 are separated from each other by a third protrusion 33 protruding from the inter-pixel isolation portion 30 to the inside of the pixel 21G. The tip end portion 331 of the third protrusion 33 is located at a position close to the optical center, and a back surface side portion 331b contains a light absorbing material.

The fourth photodiode PD4 and the first photodiode PD1 are separated from each other by a fourth protrusion 34 protruding from the inter-pixel isolation portion 30 to the inside of the pixel 21G. The tip end portion 341 of the fourth protrusion 34 is located at a position close to the optical center, and a back surface side portion 341b contains a light absorbing material.

Also in the pixel 21G, since the generation of scattered light can be suppressed, the occurrence of color mixing can be suppressed.

### (8) Eighth Modification

In the embodiment of the present disclosure, the first tip end portion 311 of the first protrusion 31 and the second tip end portion 321 of the second protrusion 32 may have an inclination (that is, the tapered shape) with respect to the thickness direction of the semiconductor substrate 10.

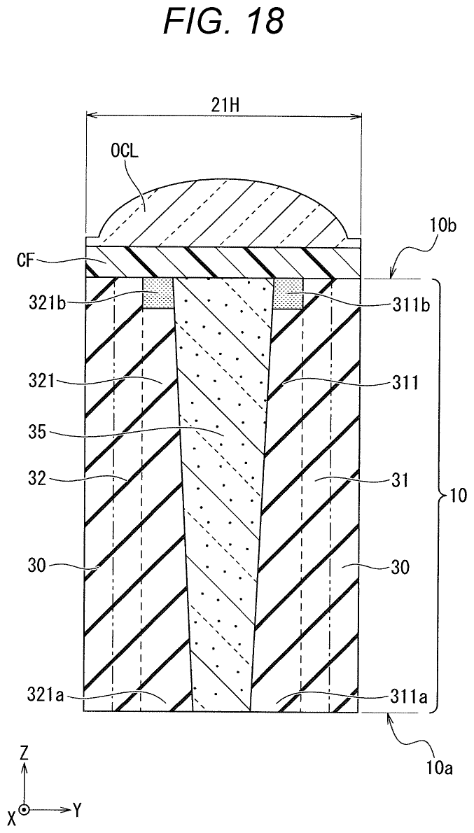

FIG. 18 is a cross-sectional view illustrating a configuration of the pixel 21H according to an eighth modification of the first embodiment of the present disclosure. FIG. 18 illustrates a cross section of a pixel 21H cut along the Z-axis direction at the same position as the line Y1-Y1′ illustrated in FIG. 2, for example. As illustrated in FIG. 18, in the pixel 21H, the first tip end portion 311 of the first protrusion 31 and the second tip end portion 321 of the second protrusion 32 are inclined with respect to the thickness direction (for example, the Z-axis direction) of the semiconductor substrate 10. For example, each of the first tip end portion 311 and the second tip end portion 321 has an inclination (that is, the inverse tapered shape) with respect to the Z-axis direction such that the gap 35 between the first tip end portion 311 and the second tip end portion 321 gradually narrows from the back surface 10b to the front surface 10a of the semiconductor substrate 10.

As illustrated in FIG. 18, in the pixel 21H, in the thickness direction (for example, the Z-axis direction) of the semiconductor substrate 10, the front surface side portion 311a of the first tip end portion 311 is at a position different from the back surface side portion 311b of the first tip end portion 311. Similarly, in the thickness direction (for example, the Z-axis direction) of the semiconductor substrate 10, the front surface side portion 321a of the second tip end portion 321 is at a position different from the back surface side portion 321b of the second tip end portion 321. The back surface side portions 311b and 321b contain a light absorbing material.

Also in the pixel 21H, since the generation of scattered light can be suppressed, the occurrence of color mixing can be suppressed.

### (9) Ninth Modification

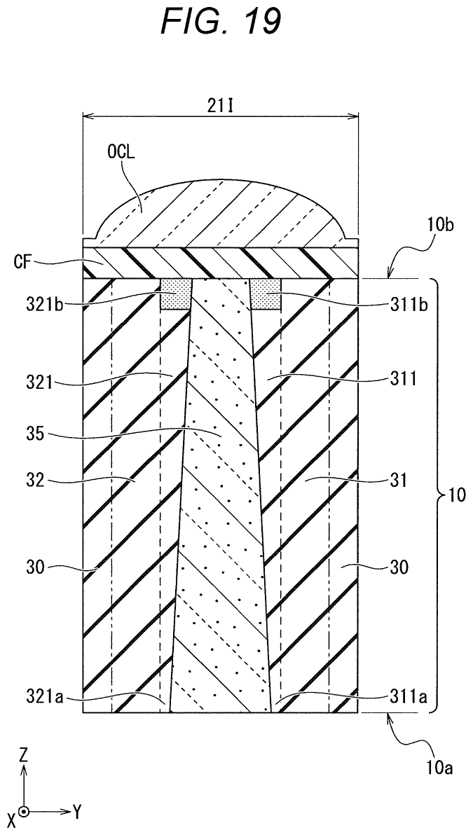

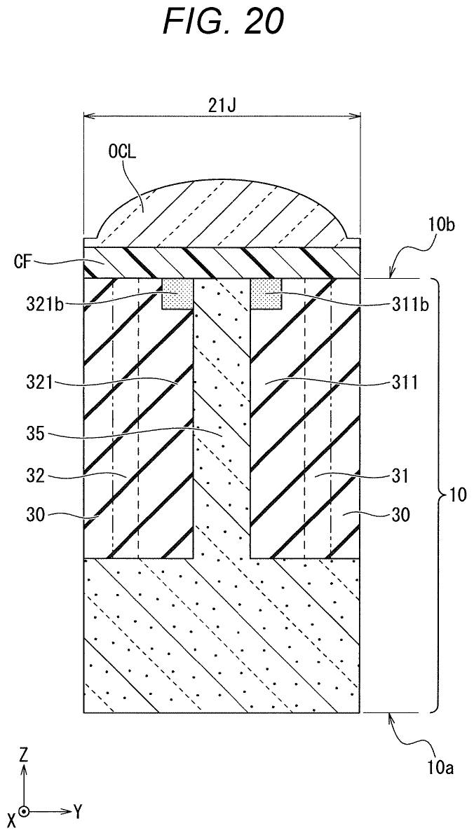

FIG. 19 is a cross-sectional view illustrating a configuration of a pixel 21I according to a ninth modification of the first embodiment of the present disclosure. FIG. 19 illustrates a cross section of the pixel 21I cut along the Z-axis direction at the same position as the line Y1-Y1′ illustrated in FIG. 2, for example. As illustrated in FIG. 19, in the pixel 21I, the first tip end portion 311 of the first protrusion 31 and the second tip end portion 321 of the second protrusion 32 are inclined with respect to the Z-axis direction. For example, each of the first tip end portion 311 and the second tip end portion 321 has an inclination (that is, the forward tapered shape) with respect to the Z-axis direction such that the gap 35 between the first tip end portion 311 and the second tip end portion 321 gradually widens from the back surface 10b to the front surface 10a of the semiconductor substrate 10.

As illustrated in FIG. 19, in the pixel 21I, in the thickness direction (for example, the Z-axis direction) of the semiconductor substrate 10, the front surface side portion 311a of the first tip end portion 311 is at a position different from the back surface side portion 311b of the first tip end portion 311. Similarly, in the thickness direction (for example, the Z-axis direction) of the semiconductor substrate 10, the front surface side portion 321a of the second tip end portion 321 is at a position different from the back surface side portion 321b of the second tip end portion 321. The back surface side portions 311b and 321b contain a light absorbing material.

Also in the pixel 21H, since the generation of scattered light can be suppressed, the occurrence of color mixing can be suppressed.

### (10) Tenth Modification

In the first embodiment described above, the case where the inter-pixel isolation portion 30, the first protrusion 31, and the second protrusion 32 are provided so as to penetrate the semiconductor substrate 10 from the back surface 10b to the front surface 10a of the semiconductor substrate 10 has been described. However, the embodiment of the present disclosure is not limited thereto.

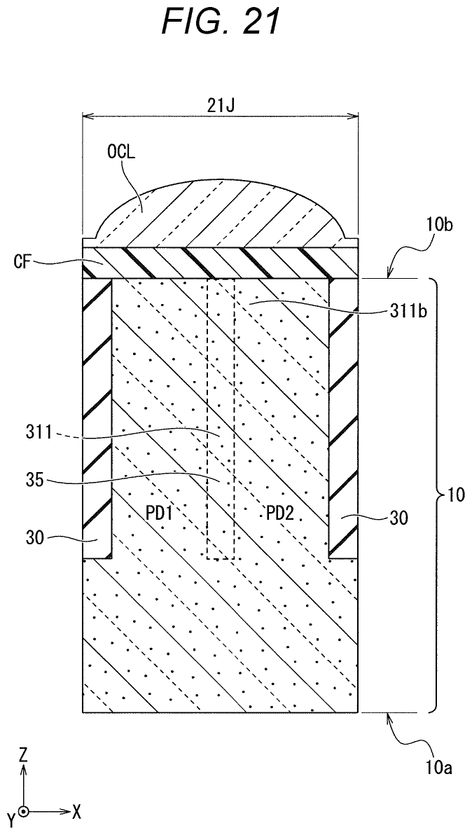

FIGS. 20 and 21 are cross-sectional views illustrating the configuration of a pixel 21J according to a tenth modification of the first embodiment of the present disclosure. FIG. 20 illustrates a cross section of the pixel 21J cut along the Z-axis direction at the same position as the line Y1-Y1′ illustrated in FIG. 2, for example. FIG. 21 illustrates a cross section of the pixel 21J cut along the Z-axis direction at the same position as the line X1-X1′ illustrated in FIG. 2, for example.

As illustrated in FIGS. 20 and 21, in the pixel 21J according to the tenth modification of the first embodiment, the inter-pixel isolation portion 30, the first protrusion 31, and the second protrusion 32 are provided from the back surface 10b of the semiconductor substrate 10 to a midway position between the back surface 10b and the front surface 10a. The inter-pixel isolation portion 30, the first protrusion 31, and the second protrusion 32 are not provided between the midway position and the front surface 10a. The back surface side portions 311b and 321b contain a light absorbing material.

Also in the pixel 21J, since the generation of scattered light can be suppressed, the occurrence of color mixing can be suppressed.

### (11) Eleventh Modification

In the above embodiment, it has been described that at least the back surface side portion 311b of the first protrusion 31 contains a material (hereinafter, also referred to as a light absorbing material) that absorbs light as compared with the inter-pixel isolation portion 30. However, the first embodiment of the present disclosure is not limited thereto. In the first embodiment of the present disclosure, a structure that absorbs light (hereinafter, also referred to as a light absorbing structure) may be used instead of the light absorbing material.

FIG. 22 is a cross-sectional view illustrating a light absorbing structure 110 according to an eleventh modification of the first embodiment of the present disclosure. The light absorbing structure 110 illustrated in FIG. 22 is provided with an oxide film 135, an intermediate second layer 136, an intermediate first layer 137, and a Si layer 138 from above. Among them, the intermediate second layer 136 and the intermediate first layer 137 serve as the reflection ratio adjusting layer. Note that the Si layer 138 may be a part of the semiconductor substrate 10 (see FIG. 4), or may be a layer provided separately from the semiconductor substrate 10.

The intermediate second layer 136 includes, for example, a material having a refractive index n2 of 1.9 or more to 2.3 or less such as SiN, HfO₂, Ta₂O₅, Nb₂O₅, and TiO₂.

Furthermore, the intermediate first layer 137 has, for example, a configuration in which a material constituting the intermediate second layer 136 and Si constituting the Si layer 138 are mixed and arranged. More specifically, an uneven structure is formed on the Si layer 138, and a recess 137a of the uneven structure is filled with the material constituting the intermediate second layer 136. The structure of the recess 137a is, for example, a prismatic shape, may be another shape, or may be a cylindrical shape.

In the intermediate first layer 137, the height d1 of the recess 137a is set in a range of about 20 nm or more and 60 nm or less. Under this setting, the volume ratio between the material constituting the Si layer 138 and the material constituting the intermediate second layer 136 in the intermediate first layer 137 is set to a predetermined value. Therefore, the refractive index n1 of the intermediate first layer 137 is adjusted to be 2.6 or more and 3.7 or less as a whole.

More specifically, it is ideal that the intermediate first layer 137 contains a substance having an extinction coefficient of 0 and a refractive index of 2.6 or more and 3.7 or less, but there is practically no substance having an extinction coefficient of 0 and a refractive index of 2.6 or more and 3.7 or less. Therefore, the intermediate first layer 137 is formed to have a refractive index n1 of 2.6 or more and 3.7 or less as a whole by mixing and arranging, with the volume ratio, a material for forming the Si layer 138 having a refractive index ns=4.1 and a refractive index adjusting material (here, the same material as the material forming the intermediate second layer 136) having a refractive index of 1.9 or more and 2.3 or less, of which the refractive index n2 is lower than that of the Si layer 138, to average the refractive indexes as a whole.

For example, it is assumed a case that a volume V1 of the recess 137a forming the intermediate first layer 137 and a volume V2 in the range containing the same material as the Si layer 138 (which is a protrusion with respect to the recess 137a) are V1:V2=3:2. In this case, when a refractive index ns of the material Si of the Si layer 138 is 4.1 and the material forming the intermediate second layer 136 is Ta₂O₅ with the refractive index n2 of 2.2, the Si layer 138 and the intermediate second layer 136 are mixed and arranged according to the volume ratio. Therefore, the intermediate first layer 137 having the averaged refractive index n1 of about 3.3 is formed.

However, in a case where the refractive index ni of the oxide film 135 of SiO₂ is 1.46 and the refractive index ns of the Si layer 138 is 4.1, a substance having another refractive index may be used to form the intermediate first layer 137 and the intermediate second layer 36 as long as refractive index ni<refractive index n2<effective refractive index n1<refractive index ns is satisfied. Note that, as for the Si layer 138, this is similar for a layer of InGaAs having a refractive index of about 4.0.

By using the light absorbing structure 110 having such a structure for the back surface side portions 311b and 321b (see, for example, FIG. 2) and the like, reflection of incident light in a wide wavelength band can be suppressed. Since the generation of scattered light can be suppressed, the occurrence of color mixing can be suppressed.

### (12) Twelfth Modification

The configuration of the light absorbing structure is not limited to the eleventh modification described above. For example, a configuration of a twelfth modification described below may be used.

FIG. 23 is a cross-sectional view illustrating a light absorbing structure 210 according to the twelfth modification of the first embodiment of the present disclosure. As illustrated in FIG. 23, the light absorbing structure 210 according to the twelfth modification of the first embodiment of the present disclosure includes a semiconductor layer 212 and a plurality of pillars 247 provided on a light-receiving surface (in FIG. 23, the upper surface) side of the semiconductor layer 212.

The plurality of pillars 247 is arranged side by side with a period smaller than a wavelength of incident light (for example, light belonging to the visible light band), and the plurality of pillars 247 constitutes an uneven structure 245. The uneven structure 245 suppresses reflection of incident light. Note that the semiconductor layer 212 may be a part of the semiconductor substrate 10 (see FIG. 4), or may be a layer provided separately from the semiconductor substrate 10.

The uneven structure 245 will be described more specifically. As illustrated in FIG. 23, the uneven structure 245 is provided by arranging a plurality of protrusion-shaped pillars 247 extending in the thickness direction of the semiconductor layer 212 at a period smaller than the wavelength of light belonging to the visible light band.

For example, the pillar 247 is provided in a tapered shape in which the area of the cross section cut in the in-plane direction of the semiconductor layer 212 decreases toward the tip end portion of a pillar 47. The cross-sectional shape of the pillar 247 cut in the in-plane direction of the semiconductor layer 212 may be, for example, a circular shape or an elliptical shape, and may be a triangular shape, a quadrangular shape, or a polygonal shape of a pentagon or more. Furthermore, the cross-sectional shape of the pillar 247 cut in the in-plane direction of the semiconductor layer 212 may be the same regardless of the cutting position, or may be different at the cutting position.

The three-dimensional shape of the pillar 247 may be a conical shape in which the shape of the tip end portion of the pillar 247 is a cone shape, a pyramid shape, or the like. Furthermore, the three-dimensional shape of the pillar 247 may be a conical shape or a shape in which the shape of the tip end portion of the pyramid shape is changed from a pyramid shape to a hemispherical shape. Moreover, the three-dimensional shape of the pillar 47 may be a truncated cone shape in which the tip end portion of the pillar 247 is a flat portion, a truncated pyramid shape, or the like.

Note that each of the plurality of pillars 247 forming the uneven structure 245 may have a similar three-dimensional shape or different three-dimensional shapes.

The uneven structure 245 is provided by two-dimensionally arranging the pillars 247. For example, the uneven structure 245 may be provided by periodically arraying the pillars 247 two-dimensionally in a tetragonal lattice array or a hexagonal close-packed array in the in-plane direction of the semiconductor layer 212. Furthermore, the uneven structure 245 may be provided by randomly arranging the pillars 247 in the in-plane direction of the semiconductor substrate 10.

The period of arranging the pillars 247 may be, for example, 200 nm or less. By setting the period of arranging the pillars 247 within the above range, the uneven structure 245 can suppress generation of diffracted light due to the periodic structure. Note that the lower limit of the period in which the pillars 247 are arranged may be 20 nm from the viewpoint of the formation process of the pillars 247.

The period of arranging the pillars 247 can be defined as, for example, the distance between the vertices that are most convex at the tip end portion of the adjacent pillars 247 or the distance between the bottom points that are most concave between the adjacent pillars 247.

Here, in the pillar 247 constituting the uneven structure 245 according to the present embodiment, the aspect ratio (h/r) obtained by dividing the height h of the pillar 247 by the diameter r of the bottom surface of the pillar in an arbitrary direction can be 1 or more.

For example, in a case where the three-dimensional shape of the pillar 247 is a conical shape, the height h of the pillar 247 can be defined as a distance from an intersection of a straight line drawn in the thickness direction of the semiconductor layer 212 from a point (that is, the vertex) that is most convex at the tip end portion of the pillar 47 and a plane passing through each point that is most recessed between adjacent pillars 247 to a point (that is, the vertex) that is most convex at the tip end portion of the pillar 47.

Furthermore, the diameter r of the bottom surface of the pillar 247 in an arbitrary direction can be defined as a diameter in an arbitrary direction of a cross-sectional shape obtained by cutting the pillar 247 in a plane passing through each point that is most recessed between the adjacent pillars 247. Note that, in a case where the cross-sectional shape obtained by cutting the pillar 247 is a flat shape such as an elliptical shape, the diameter in the arbitrary direction is defined as the diameter on the major axis side. Furthermore, in a case where the cross-sectional shape obtained by cutting the pillar 247 is a polygonal shape, the diameter of the circumscribed circle of the polygonal shape is defined as the diameter in an arbitrary direction of the bottom surface of the pillar 247.

In the imaging device 1 according to the present embodiment, the aspect ratio (h/r) of the pillars 247 derived on the basis of the above definition can be 1 or more. The uneven structure 245 including such pillars 247 can increase the distance by which the refractive index changes with respect to the incident light in the thickness direction of the semiconductor layer 212. Therefore, since the uneven structure 245 can make the change in the refractive index with respect to the incident light gentler, it is possible to further suppress the reflection of the incident light.

By using the light absorbing structure 210 having such a structure for the back surface side portions 311b and 321b (see, for example, FIG. 2) and the like, reflection of incident light in a wide wavelength band can be suppressed. Since the generation of scattered light can be suppressed, the occurrence of color mixing can be suppressed.

### SECOND EMBODIMENT

Next, as a second embodiment of the present disclosure, a method of manufacturing a pixel described in the first embodiment will be described. In the following Methods 1 and 2, a method of manufacturing the pixel 21 illustrated in FIG. 4 and the like will be described. In Methods 3 and 4, a method of manufacturing the pixel 21A illustrated in FIG. 10 and the like will be described.

Note that the imaging device 1 including the pixel 21 is manufactured by using various devices such as a film forming device (including a chemical vapor deposition (CVD) device and a sputtering device), an ion implantation device, a heat treatment device, an etching device, a chemical mechanical polishing (CMP) device, and a bonding device. Hereinafter, these devices are collectively referred to as manufacturing apparatuses.

### (1) First Method

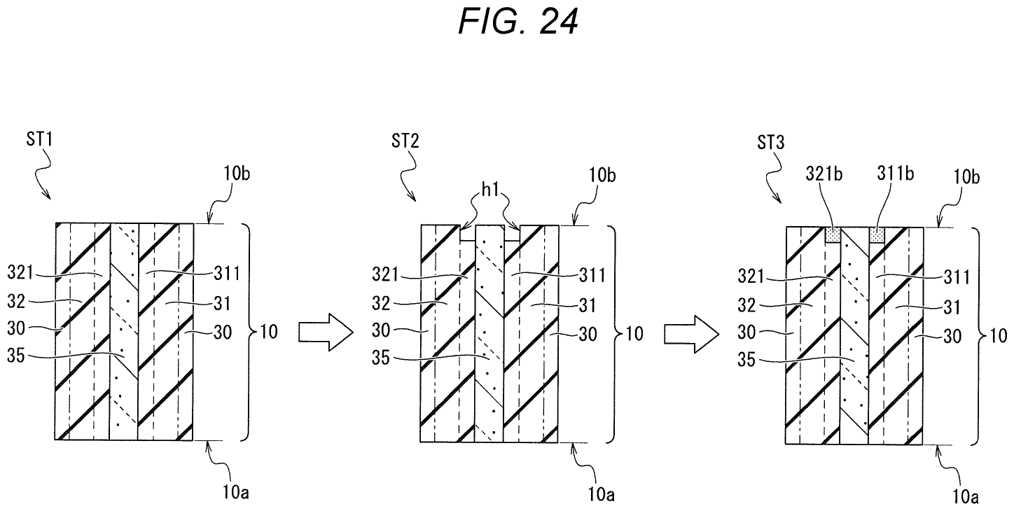

FIG. 24 is a cross-sectional view illustrating a manufacturing method (first method) of the pixel 21 according to the second embodiment of the present disclosure in order of steps. In step ST1 of FIG. 24, the semiconductor substrate 10 is provided with the inter-pixel isolation portion 30 so as to penetrate between the front surface 10a and the back surface 10b, the first protrusion 31 in which the back surface side portion 311b is not formed, and the second protrusion 32 in which the back surface side portion 321b is not formed. The semiconductor substrate 10 includes, for example, silicon (Si). The inter-pixel isolation portion 30, the first protrusion 31, and the second protrusion include, for example, a silicon oxide film (SiO).

As illustrated in step ST2 of FIG. 24, the manufacturing apparatus etches the first tip end portion 311 of the first protrusion 31 and the second tip end portion 321 of the second protrusion 32 from the back surface 10b side of the semiconductor substrate 10 to form an opening h1. The etching may be either dry etching or wet etching.

Next, as illustrated in step ST3 of FIG. 24, the manufacturing apparatus embeds a light absorbing material in the opening h1 provided on the back surface 10b side of the semiconductor substrate 10. For example, a light absorbing material is formed on the back surface 10b side of the semiconductor substrate 10 by a CVD method or a sputtering method to fill the opening h1. Next, the manufacturing apparatus performs CMP treatment on the formed light absorbing material to remove the light absorbing material from the region other than the opening h1. Therefore, the back surface side portions 311b and 321b containing the light absorbing material are formed. Through such steps, the pixel 21 illustrated in FIG. 4 and the like is completed.

### (2) Second Method

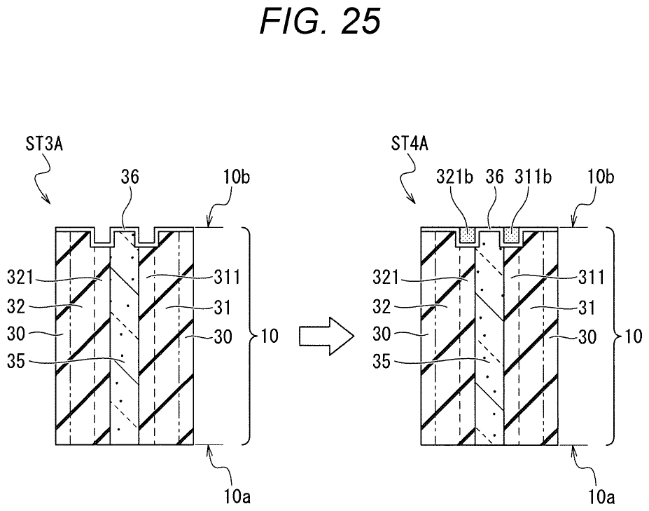

FIG. 25 is a cross-sectional view illustrating a manufacturing method (second method) of the pixel 21 according to the second embodiment of the present disclosure in order of steps. In this second method, after step ST2 illustrated in FIG. 24, the process proceeds to step ST3A in FIG. 25. In step ST3A, the manufacturing apparatus forms a liner film such as an oxide film (for example, SiO) on the back surface 10b side of the semiconductor substrate 10. The liner film is a thin film covering the surface. The liner film is formed by, for example, a CVD method or an atomic layer deposition (ALD) method.

Next, the process proceeds to step ST4A in FIG. 25. In step ST4A of FIG. 25, similarly to step ST3 described above, the manufacturing apparatus embeds a light absorbing material in the opening h1 provided on the back surface 10b side of the semiconductor substrate 10. Through such steps, the pixel 21 illustrated in FIG. 4 and the like is completed.

### (3) Third Method

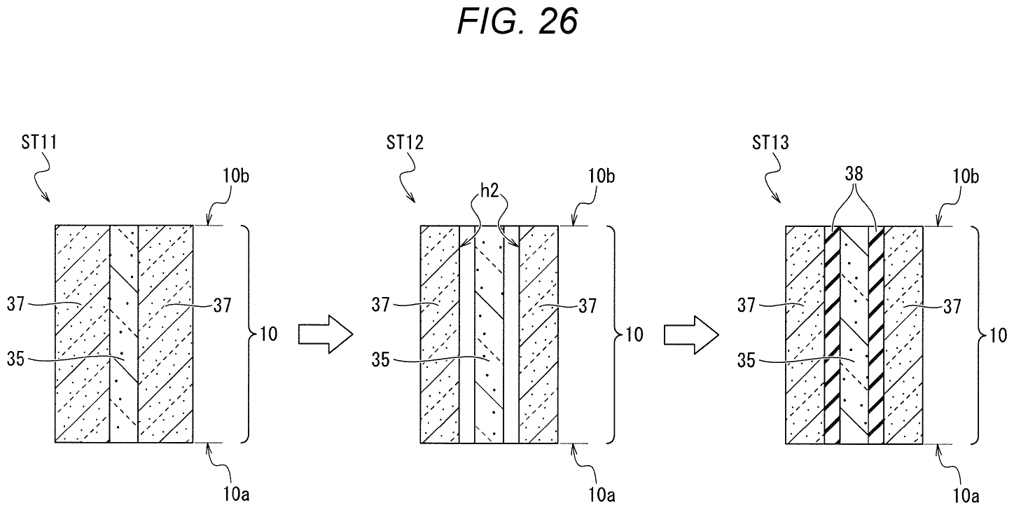

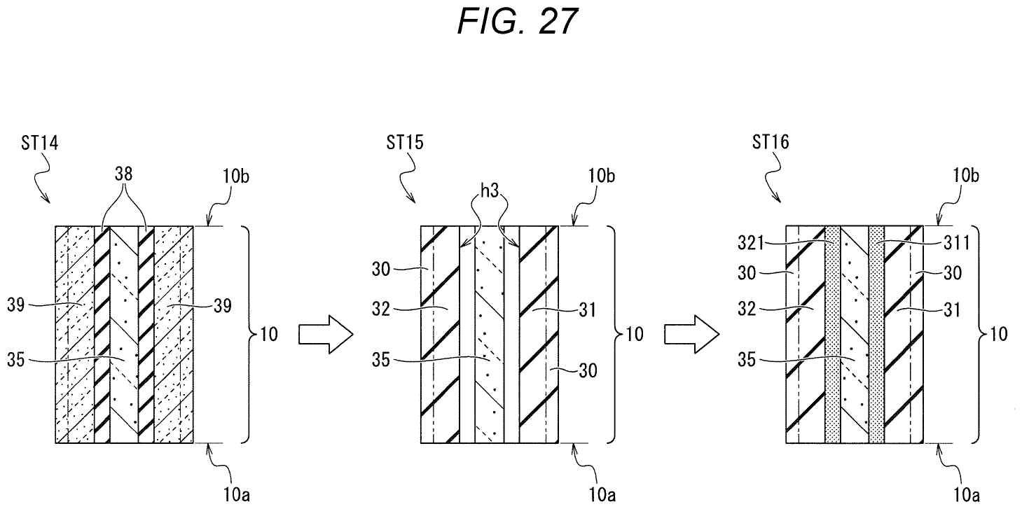

FIGS. 26 and 27 are cross-sectional views illustrating a manufacturing method (third method) of the pixel 21A according to the second embodiment of the present disclosure in order of steps. In step ST11 of FIG. 26, a polycrystalline silicon film 37 is formed in a predetermined region where the inter-pixel isolation portion 30 (see FIG. 10) is to be formed, a predetermined region where the first protrusion 31 (see FIG. 10) including the first tip end portion 311 is to be formed, and a predetermined region where the second protrusion 32 (see FIG. 10) including the second tip end portion 321 is to be formed.

Next, as shown in step ST12 of FIG. 26, the manufacturing apparatus forms a through hole h2 in a predetermined region where the first protrusion 31 is to be formed and a predetermined region where the second protrusion 32 is to be formed. The through hole h2 is formed by selectively etching the polycrystalline silicon film 37 from the back surface 10b side of the semiconductor substrate 10. This etching is performed by dry etching.

Next, as illustrated in step ST13 of FIG. 26, the manufacturing apparatus fills a silicon nitride film (SiN) 38 in the through hole h2. For example, the silicon nitride film 38 is formed by the CVD method to fill the through hole h2. Next, the manufacturing apparatus performs CMP treatment on the formed silicon nitride film 38 to remove the silicon nitride film 38 from the region other than the through hole h2. Therefore, a structure in which the silicon nitride film 38 remains only in the through hole h2 is formed.

Next, as shown in step ST14 of FIG. 27, the manufacturing apparatus replaces the polycrystalline silicon film 37 (see FIG. 26) with a silicon oxide film (SiO) 39. For example, the manufacturing apparatus etches and removes the polycrystalline silicon film 37 under the condition that the polycrystalline silicon film 37 is more easily etched than the silicon nitride film 38. This etching is performed by, for example, dry etching. Furthermore, this etching is not limited to dry etching, and may be performed by wet etching. Therefore, a through hole is formed in a predetermined region where the inter-pixel isolation portion 30 is to be formed, a predetermined region where the first protrusion 31 is to be formed (however, the first tip end portion 311 is excluded), and a predetermined region where the second protrusion 32 is to be formed (however, the second tip end portion 321 is excluded). Next, the manufacturing apparatus forms the silicon oxide film 39 so as to fill the through hole. The silicon oxide film 39 is formed by, for example, a CVD method. Furthermore, the formation of the silicon oxide film 39 is not limited to the CVD method, and may be performed by the ALD method. Therefore, the polycrystalline silicon film 37 is replaced with the silicon oxide film 39.

Next, as illustrated in step ST15 of FIG. 27, the manufacturing apparatus etches and removes the silicon nitride film 38 to form a through hole h3. For example, the manufacturing apparatus etches and removes the silicon nitride film 38 under the condition that the silicon nitride film 38 is more easily etched than the silicon oxide film 39. The etching may be either wet etching or dry etching. Therefore, the through hole h3 is formed in each of a predetermined region where the first tip end portion 311 of the first protrusion 31 is to be formed and a predetermined region where the second tip end portion 321 of the second protrusion 32 is to be formed. Furthermore, the inter-pixel isolation portion 30, the first protrusion 31 other than the first tip end portion 311, and the second protrusion other than the second tip end portion 321 include the silicon oxide film 39.

Next, as shown in step ST16 of FIG. 27, the manufacturing apparatus embeds a light absorbing material in the through hole h3. For example, the manufacturing apparatus forms a polycrystalline silicon film (an example of a light absorbing member) by a CVD method to fill the through hole h3. Next, the manufacturing apparatus performs CMP treatment on the formed polycrystalline silicon film, and removes the polycrystalline silicon film from the region other than the through hole h3. Therefore, the polycrystalline silicon film remains only in the through hole h3, and the first tip end portion 311 of the first protrusion 31 and the second tip end portion 321 of the second protrusion 32 are formed. Through such steps, the pixel 21A illustrated in FIG. 10 and the like is completed.

### (4) Fourth Method

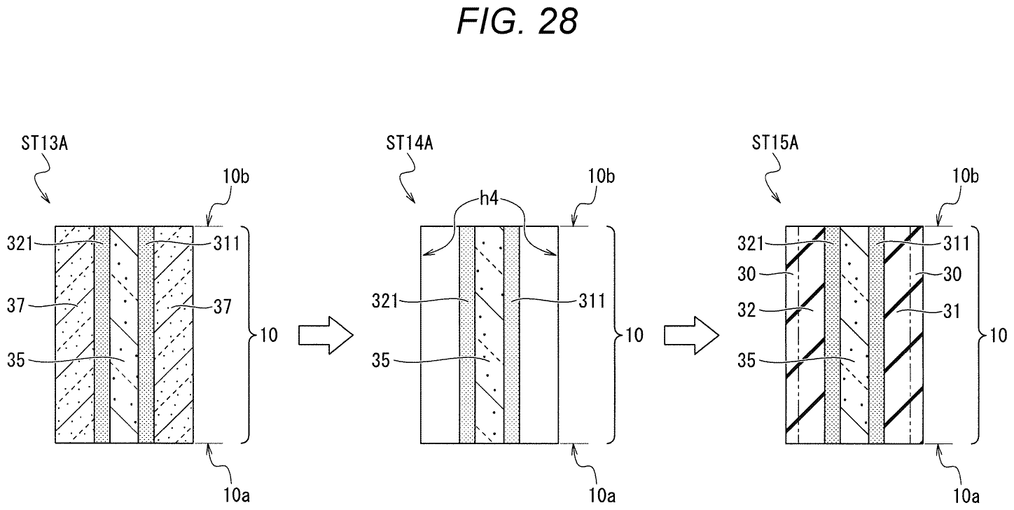

FIG. 28 is a cross-sectional view illustrating a manufacturing method (fourth method) of the pixel 21A according to the second embodiment of the present disclosure in order of steps. In this fourth method, after step ST12 illustrated in FIG. 26, the process proceeds to step ST13A in FIG. 28. In step ST13A, the manufacturing apparatus embeds a light absorbing material in the through hole h3. For example, the manufacturing apparatus forms a silicon nitride film (an example of a light absorbing member) by a CVD method to fill the through hole h3. Next, the manufacturing apparatus performs CMP treatment on the formed silicon nitride film to remove the silicon nitride film from the region other than the through hole h3. Therefore, the silicon nitride film remains only in the through hole h3, and the first tip end portion 311 of the first protrusion 31 and the second tip end portion 321 of the second protrusion 32 are formed.

Next, in step ST14A of FIG. 28, the manufacturing apparatus etches and removes the polycrystalline silicon film 37 to form a through hole h4. For example, the manufacturing apparatus etches and removes the polycrystalline silicon film 37 under the condition that the polycrystalline silicon film 37 is more easily etched than the silicon nitride film constituting the first tip end portion 311 and the second tip end portion 321. This etching is performed by dry etching. Furthermore, this etching is not limited to dry etching, and may be performed by wet etching. Therefore, the through hole h4 is formed in each of a predetermined region where the inter-pixel isolation portion 30 is to be formed, a predetermined region where the first protrusion 31 is to be formed (however, the first tip end portion 311 is excluded), and a predetermined region where the second protrusion 32 is to be formed (however, the second tip end portion 321 is excluded).

Next, as illustrated in step ST15A of FIG. 28, the manufacturing apparatus embeds a low refractive index film having a refractive index lower than that of the light absorbing member (for example, a silicon nitride film) constituting the first tip end portion 311 and the second tip end portion 321 in the through hole h4 to form the inter-pixel isolation portion 30, the first protrusion 31 (however, the first tip end portion 311 is excluded), and the second protrusion 32 (however, the second tip end portion 321 is excluded).

For example, the manufacturing apparatus forms a silicon oxide film (an example of a low refractive index film) by a CVD method to fill the through hole h4. Next, the manufacturing apparatus performs CMP treatment on the formed silicon oxide film to remove the silicon oxide film from the region other than the through hole h4. Therefore, the silicon oxide film remains only in the through hole h4, and the inter-pixel isolation portion 30, the first protrusion 31 (however, the first tip end portion 311 is excluded), and the second protrusion 32 (however, the second tip end portion 321 is excluded) are formed. Through such steps, the pixel 21A illustrated in FIG. 10 and the like is completed.

### THIRD EMBODIMENT

### Configuration Example

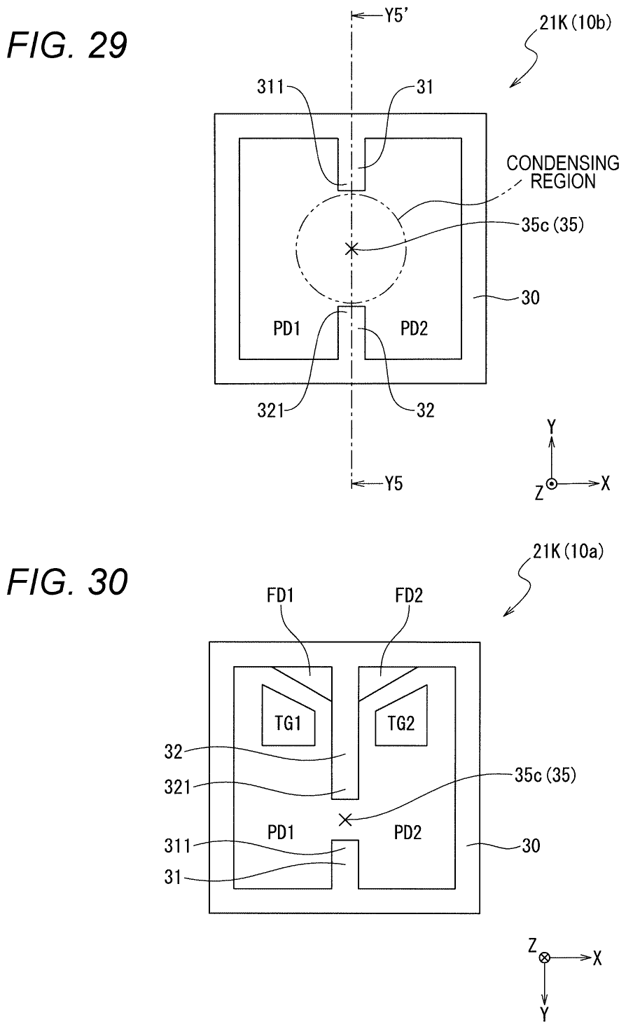

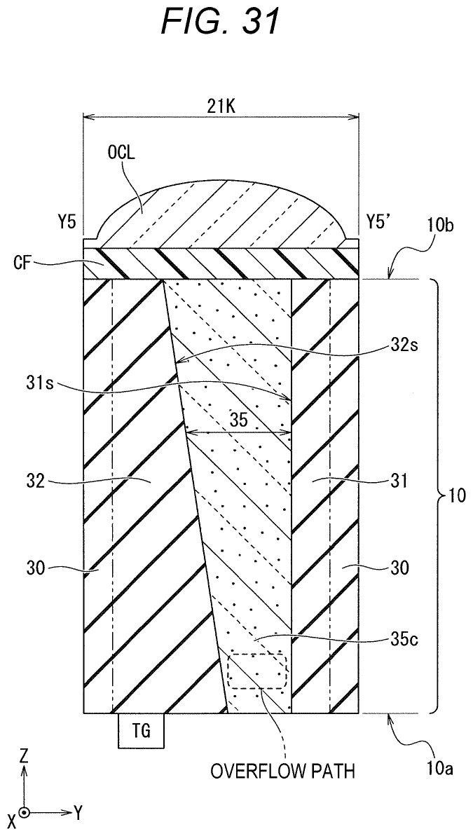

FIGS. 29 and 30 are plan views illustrating configuration examples of a pixel 21K according to a third embodiment of the present disclosure. FIG. 29 is a diagram of the pixel 21 as viewed from the back surface 10b side of the semiconductor substrate 10, and FIG. 30 is a diagram of the pixel 21 as viewed from the front surface 10a side of the semiconductor substrate. FIG. 31 is a cross-sectional view illustrating a configuration example of the pixel 21K according to the third embodiment of the present disclosure. FIG. 31 corresponds to a cross section of the plan view of FIG. 29 taken along line Y5-Y5′. Note that, in FIG. 29, illustration of the on-chip lens OCL and the color filter CF is omitted in order to illustrate an inter-pixel isolation portion 30, a first protrusion 31, and a second protrusion 32.

As illustrated in FIGS. 29 to 31, in the pixel 21K according to the third embodiment, unlike the pixels 21 to 21J according to the first embodiment, the light absorbing material or the light absorbing structure such as the back surface side portion 311b (see FIGS. 2 and 4) may not be provided in the first protrusion 31. Similarly, the second protrusion 32 may not be provided with a light absorbing material or a light absorbing structure like the back surface side portion 321b (see FIGS. 2 and 4).

As illustrated in FIG. 29, when the pixel 21K is viewed from the back surface 10b side of the semiconductor substrate 10, the first protrusion 31 and the second protrusion 32 are preferably arranged at positions deviated from a condensing region where the on-chip lens OCL condenses light. When the pixel 21K is viewed from the back surface 10b side of the semiconductor substrate 10, the gap 35 between the first protrusion 31 and the second protrusion 32 is preferably located in the condensing region. Therefore, it is possible to suppress light from hitting the first tip end portion 311 of the first protrusion 31 and the second tip end portion 321 of the second protrusion 32, and thus, it is possible to suppress generation of scattered light.

Furthermore, in the pixel 21K, in the direction in which the first protrusion 31 and the second protrusion 32 face each other (for example, the Y-axis direction), a central position 35c of the gap 35 is different between the back surface 10b and the front surface 10a. For example, on the back surface 10b side of the semiconductor substrate 10, the central position 35c of the gap 35 is located in a condensing region where the on-chip lens OCL condenses light, and is located, for example, in the central portion of the pixel 21K. On the other hand, on the front surface 10a side of the semiconductor substrate 10, the central position 35c of the gap 35 is located outside the central portion of the pixel 21K.

More specifically, as illustrated in FIG. 31, the first protrusion 31 has a side surface 31s facing the gap 35. The side surface 31s is also an end surface of the first tip end portion 311 of the first protrusion 31. Similarly, the second protrusion 32 has a side surface 32s facing the gap 35. The side surface 32s is also an end surface of the second tip end portion 321 of the second protrusion 32. In the example illustrated in FIG. 31, the side surface 31s is parallel to the thickness direction (for example, the Z-axis direction) of the semiconductor substrate 10, whereas the side surface 32s is inclined with respect to the thickness direction of the semiconductor substrate 10. The side surface 32s has an inclination gradually approaching the side surface 31s from the back surface 10b toward the front surface 10a.

Therefore, the length of the gap 35 gradually decreases from the back surface 10b toward the front surface 10a. From the back surface 10b to the front surface 10a, the central position 35c of the gap 35 is gradually shifted from the central portion of the pixel 21K to the outside thereof. Therefore, an overflow path serving as a transfer path of saturated charges between the first photodiode PD1 and the second photodiode PD2 can be moved away from the transfer gate TG. That is, the potential of the overflow path can be suppressed from varying by the voltage applied to the transfer gate TG.

### Manufacturing Method

Next, the following Methods 1 and 2 will be described as methods of manufacturing the pixel 21K illustrated in FIGS. 29 to 31.

### (1) First Method

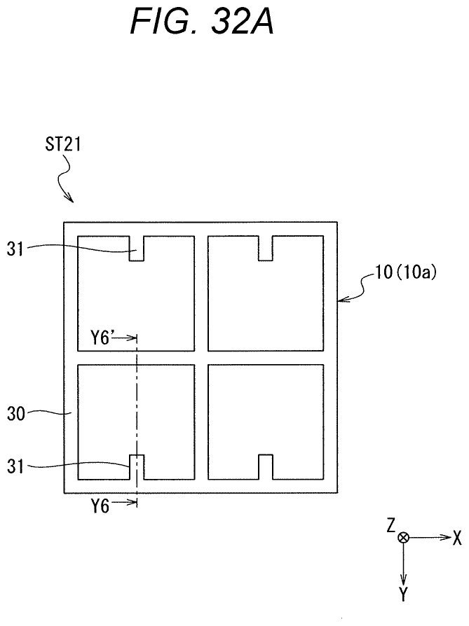

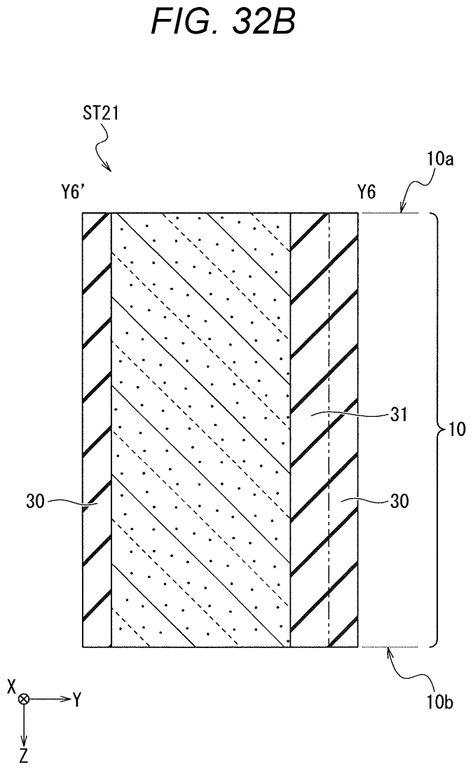

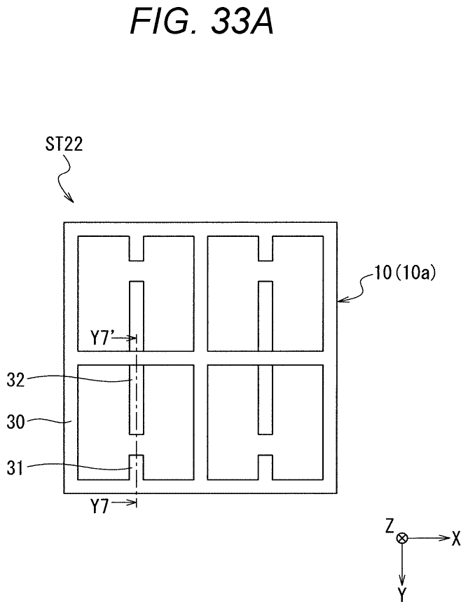

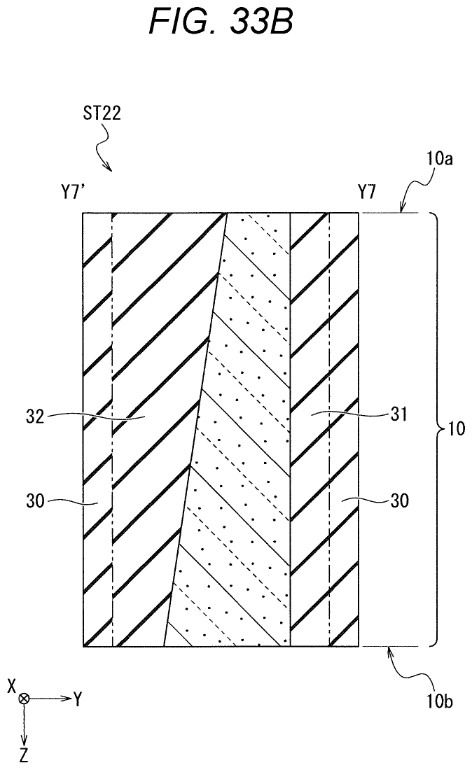

FIGS. 32A to 33B are diagrams illustrating the manufacturing method (first method) of the pixel 21K according to the third embodiment of the present disclosure in the order of processes. FIGS. 32A and 33A are plan views, and FIGS. 32B and 33B are cross-sectional views. FIG. 32B corresponds to a cross section of FIG. 32A taken along line Y6-Y6′, and FIG. 33B corresponds to a cross section of FIG. 32A taken along line Y7-Y7′. Note that, in FIGS. 32B and 33B, the front surface 10a of the semiconductor substrate 10 is located on the upper side, and the back surface 10b is located on the lower side.

As illustrated in FIGS. 32A and 32B, the manufacturing apparatus performs patterning and processing on the semiconductor substrate 10 to form the inter-pixel isolation portions 30 and the first protrusions 31 on the semiconductor substrate 10 (step ST21). For example, the manufacturing apparatus etches the semiconductor substrate 10 from the front surface 10a side to form a through hole in the predetermined region where the inter-pixel isolation portion 30 is to be formed and a predetermined region where the first protrusion 31 is to be formed. This etching is performed by dry etching.

Next, the manufacturing apparatus forms a silicon oxide film (SiO) on the front surface 10a of the semiconductor substrate 10 to fill the through hole provided in the semiconductor substrate 10. Next, the manufacturing apparatus performs CMP treatment on the formed silicon oxide film to remove the silicon oxide film from the region other than the through hole. Therefore, the silicon oxide film is left only in the through hole, and the inter-pixel isolation portion 30 and the first protrusion 31 are formed on the semiconductor substrate 10.

Next, as illustrated in FIGS. 33A and 33B, the manufacturing apparatus performs patterning and processing on the semiconductor substrate 10 to form the second protrusion 32 on the semiconductor substrate 10 (step ST22). For example, the manufacturing apparatus etches the semiconductor substrate 10 from the front surface 10a side to form a through hole in a predetermined region where the second protrusion 32 is to be formed. This etching is dry etching, and is performed with processing conditions (etching gas, bias, etc.) changed from those in step ST21 so as to be more tapered than the dry etching in step ST21.

Next, the manufacturing apparatus forms a silicon oxide film (SiO) on the front surface 10a of the semiconductor substrate 10 to fill the through hole provided in the semiconductor substrate 10. Next, the manufacturing apparatus performs CMP treatment on the formed silicon oxide film to remove the silicon oxide film from the region other than the through hole. Therefore, the silicon oxide film is left only in the through hole, and the second protrusion 32 is formed on the semiconductor substrate 10. Through such steps, the pixel 21K illustrated in FIGS. 29 to 31 is completed.

### (2) Second Method

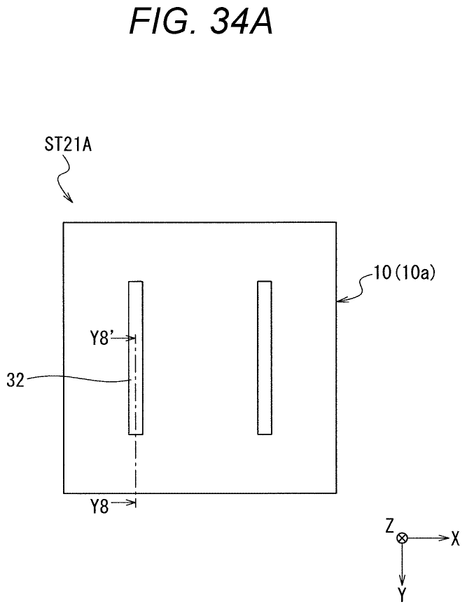

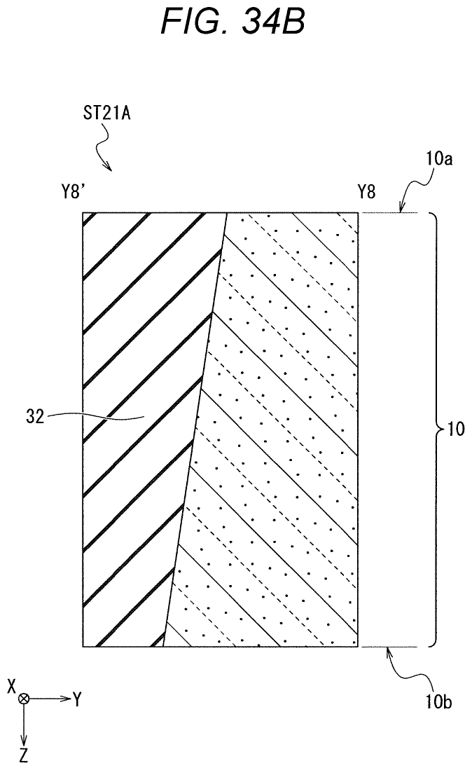

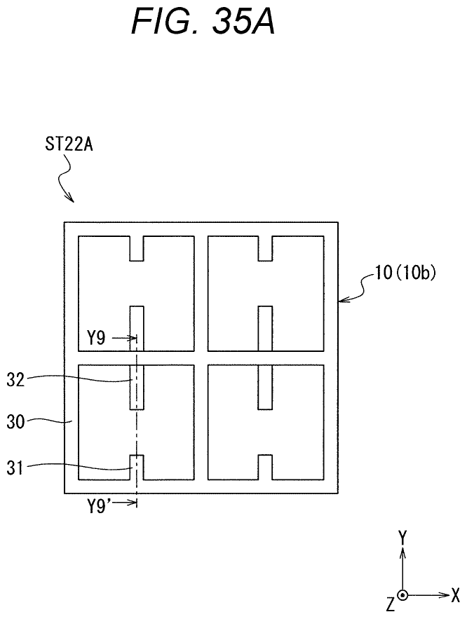

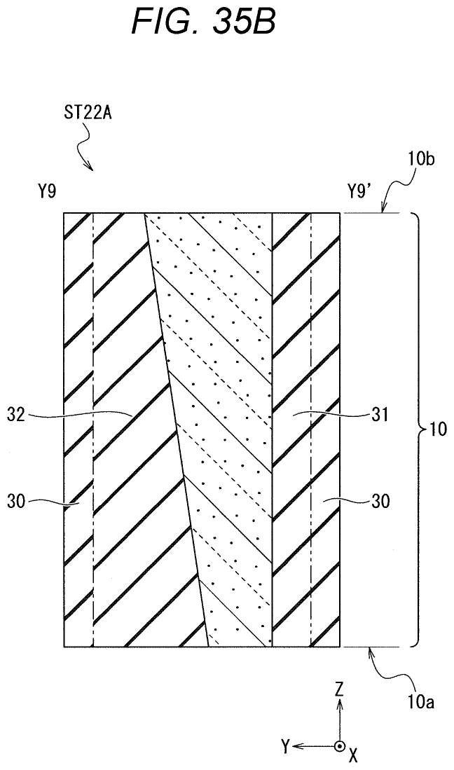

FIGS. 34A to 35B are diagrams illustrating the manufacturing method (second method) of the pixel 21K according to the third embodiment of the present disclosure in the order of processes. FIGS. 34A and 35A are plan views, and FIGS. 34B and 34B are cross-sectional views. FIG. 34B corresponds to a cross section of FIG. 34A taken along line Y8-Y8′, and FIG. 32B corresponds to a cross section of FIG. 32A taken along line Y9-Y9′. Note that, in FIGS. 34B, the front surface 10a of the semiconductor substrate 10 is located on the upper side, and the back surface 10b is located on the lower side. In FIG. 35B, the back surface 10b of the semiconductor substrate 10 is located on the upper side, and the front surface 10a is located on the lower side.

In the second method, contrary to the first method, the second protrusion 32 is formed first, and then the inter-pixel isolation portion 30 and the first protrusion 31 are formed. That is, as illustrated in FIGS. 34A and 34B, the manufacturing apparatus performs patterning and processing on the semiconductor substrate 10 to form the second protrusion 32 on the semiconductor substrate 10 (step ST21A). For example, the manufacturing apparatus etches the semiconductor substrate 10 from the front surface 10a side to form a through hole in a predetermined region where the second protrusion 32 is to be formed. This etching is dry etching, and is performed under processing conditions so as to be more tapered than dry etching in step ST22A described later.

Next, the manufacturing apparatus forms a silicon oxide film (SiO) on the front surface 10a of the semiconductor substrate 10 to fill the through hole provided in the semiconductor substrate 10. Next, the manufacturing apparatus performs CMP treatment on the formed silicon oxide film to remove the silicon oxide film from the region other than the through hole. Therefore, the silicon oxide film is left only in the through hole, and the second protrusion 32 is formed on the semiconductor substrate 10.

Next, the manufacturing apparatus performs patterning and processing on the semiconductor substrate 10 to form the inter-pixel isolation portions 30 and the first protrusions 31 on the semiconductor substrate 10 (step ST22A). For example, the manufacturing apparatus etches the semiconductor substrate 10 from the front surface 10a side to form a through hole in the predetermined region where the inter-pixel isolation portion 30 is to be formed and a predetermined region where the first protrusion 31 is to be formed. This etching is performed by dry etching.

Next, the manufacturing apparatus forms a silicon oxide film (SiO) on the front surface 10a of the semiconductor substrate 10 to fill the through hole provided in the semiconductor substrate 10. Next, the manufacturing apparatus performs CMP treatment on the formed silicon oxide film to remove the silicon oxide film from the region other than the through hole. Therefore, the silicon oxide film is left only in the through hole, and the inter-pixel isolation portion 30 and the first protrusion 31 are formed on the semiconductor substrate 10. Through such steps, the pixel 21K illustrated in FIGS. 29 to 31 is completed.

### Effect of Third Embodiment

As described above, the imaging device 1 according to the third embodiment of the present disclosure includes the semiconductor substrate 10 having the back surface 10b on which light is incident and the front surface 10a located on the opposite side of the back surface 10b, the plurality of pixels 21K provided on the semiconductor substrate 10 and performing photoelectric conversion on light, the inter-pixel isolation portion 30 provided on the semiconductor substrate 10 and isolating one pixel 21K and the other pixel 21K adjacent to each other among the plurality of pixels 21K, the first protrusion 31 provided on the semiconductor substrate 10 and protruding from the inter-pixel isolation portion 30 to the inside of the pixel 21K, and the second protrusion 32 provided at the position facing the first protrusion 31 on the semiconductor substrate 10 and protruding from the inter-pixel isolation portion 30 to the inside of the pixel 21K. A gap 35 exists between the first protrusion 31 and the second protrusion 32. In the direction in which the first protrusion 31 and the second protrusion 32 face each other, the central position 35c of the gap 35 is different between the back surface 10b and the front surface 10a.

According to this, in the back surface 10b on which light is incident, the gap 35 can be arranged at the central portion of the pixel 21K, and the first protrusion 31 and the second protrusion 32 can be arranged outside the central portion of the pixel 21K. Light can be prevented from being applied to the first protrusion 31 and the second protrusion 32 as much as possible, and reflection and scattering of light can be suppressed. Since it is possible to suppress generation of scattered light by light hitting the first protrusion 31 and the second protrusion 32, it is possible to suppress occurrence of color mixing between the pixels 21K.

Furthermore, in plan view from the thickness direction (for example, the Z-axis direction) of the semiconductor substrate 10, the central position 35c of the gap 35 on the front surface 10a of the semiconductor substrate 10 is located on the side farther from the transfer gate TG than the central position 35c of the gap 35 on the back surface 10b. The gap 35 functioning as an overflow path is disposed away from the transfer gate TG. Therefore, it is possible to suppress the potential of the overflow path from unintentionally varying due to the influence of the bias of the transfer gate TG.

### Modifications

Next, modifications of the third embodiment of the present disclosure will be described. In the embodiment of the present disclosure, the shape of the first tip end portion 311 of the first protrusion 31 in plan view and the shape of the second tip end portion 321 of the second protrusion 32 in plan view may be different from each other. By changing the shapes (that is, the layout) of the first tip end portion 311 and the second tip end portion 321 in plan view, it is possible to change how the side surfaces (for example, side surfaces 31s and 32s illustrated in FIG. 31) of the first tip end portion 311 and the second tip end portion 321 are tapered. By making the layouts of the first tip end portion 311 and the second tip end portion 321 different from each other, the first protrusion 31 and the second protrusion 32 may be patterned and processed collectively instead of separately forming the first protrusion 31 and the second protrusion 32 as in the above-described manufacturing method (Methods 1 and 2).

### (1) First Modification

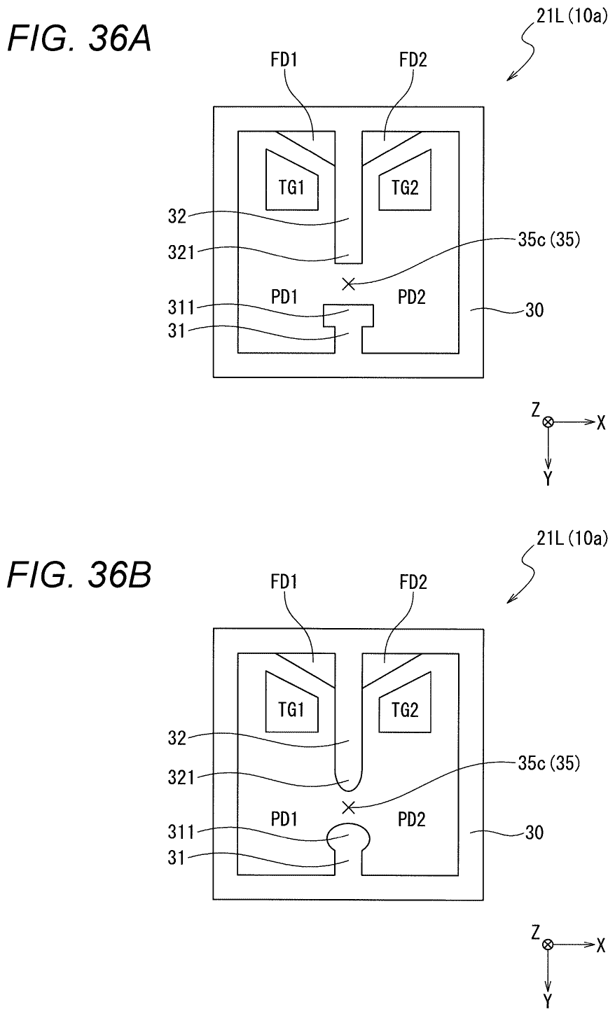

FIGS. 36A and 36B are plan views illustrating a pixel 21L according to the first modification of the third embodiment of the present disclosure. FIG. 36A illustrates a mask shape (that is, the shape in design) of the pixel 21L, and FIG. 36B illustrates an actual finished shape of the pixel 21L.

Here, as the miniaturization of pixels progresses, corners of the pattern may be rounded due to a limit of processing accuracy of patterning, and a difference may occur between the mask shape and the actual finished shape. Assuming such a case, in the first modification of the third embodiment, a mask shape of the pixel 21L is illustrated in FIG. 36A, and an actual finished shape of the pixel 21L is illustrated in FIG. 36B. However, the pixel 21L is not limited to the shape of FIG. 36B. The pixel 21L may have the shape of FIG. 36A or an intermediate shape between FIGS. 36A and 36B. The same applies to the second to fourth modifications described later.

As illustrated in FIGS. 36A and 36B, in the pixel 21L according to the first modification of the third embodiment, the first tip end portion 311 of the first protrusion 31 has a shape (hereinafter, referred to as a hammer shape) having a line width larger than that of a portion other than the first tip end portion 311 in the first protrusion 31 in plan view. Furthermore, the first tip end portion 311 having a hammer shape has a larger line width in plan view than the second protrusion 32 including the second tip end portion 321.

Therefore, even in a case where the first protrusion 31 and the second protrusion 32 are collectively patterned and processed, as illustrated in FIG. 31, for example, the side surface 32s of the second protrusion 32 can be inclined (that is, a taper is applied) with respect to the Z-axis direction more than the side surface 31s of the first protrusion 31. Therefore, there is a possibility that the number of processes of pixel manufacturing can be reduced.

### (2) Second Modification

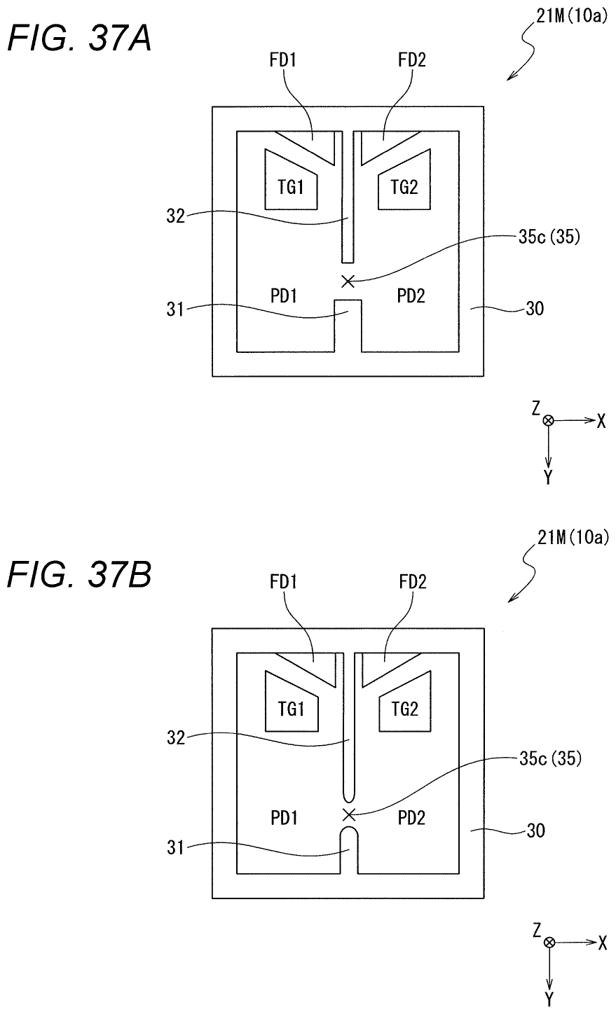

FIGS. 37A and 37B are plan views illustrating a pixel 21M according to a second modification of the third embodiment of the present disclosure. FIG. 37A illustrates a mask shape of the pixel 21M, and FIG. 37B illustrates an actual finished shape of the pixel 21M.

As illustrated in FIGS. 37A and 37B, in the pixel 21M according to the second modification of the third embodiment, the second protrusion 32 has a line width (in FIGS. 37A and 37B, the length in the X-axis direction) smaller than that of the first protrusion 31 in plan view. Therefore, similarly to the first modification, even in the second modification, the side surface 32s of the second protrusion 32 can be tapered. In a case where the first protrusion 31 and the second protrusion 32 are collectively patterned and processed, for example, as illustrated in FIG. 31, the side surface 32s of the second protrusion 32 can be inclined with respect to the Z-axis direction more than the side surface 31s of the first protrusion 31. Therefore, there is a possibility that the number of processes of pixel manufacturing can be reduced.

### (3) Third Modification

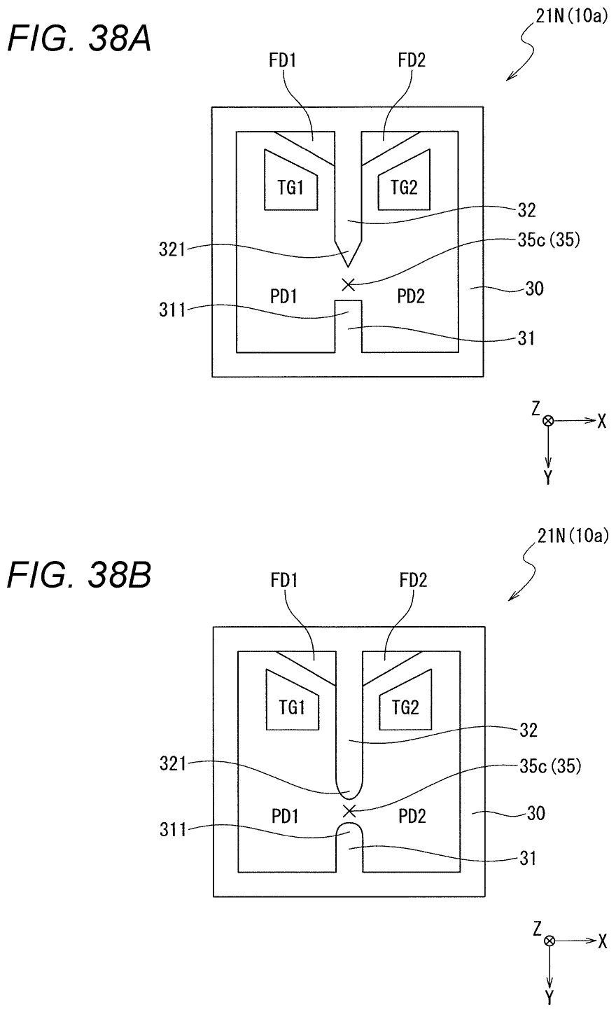

FIGS. 38A and 38B are plan views illustrating a pixel 21N according to the third modification of the third embodiment of the present disclosure. FIG. 38A illustrates a mask shape of the pixel 21N, and FIG. 38B illustrates an actual finished shape of the pixel 21N.

As illustrated in FIGS. 38A and 38B, in the pixel 21N according to the third modification of the third embodiment, the second tip end portion 321 of the second protrusion 32 has a shape with a narrower tip end portion in plan view than the first tip end portion 311 of the first protrusion 31. Therefore, similarly to the first and second modifications, even in the third modification, the side surface 32s of the second protrusion 32 can be tapered. In a case where the first protrusion 31 and the second protrusion 32 are collectively patterned and processed, for example, as illustrated in FIG. 31, the side surface 32s of the second protrusion 32 can be inclined with respect to the Z-axis direction more than the side surface 31s of the first protrusion 31. Therefore, there is a possibility that the number of processes of pixel manufacturing can be reduced.

### (4) Fourth Modification

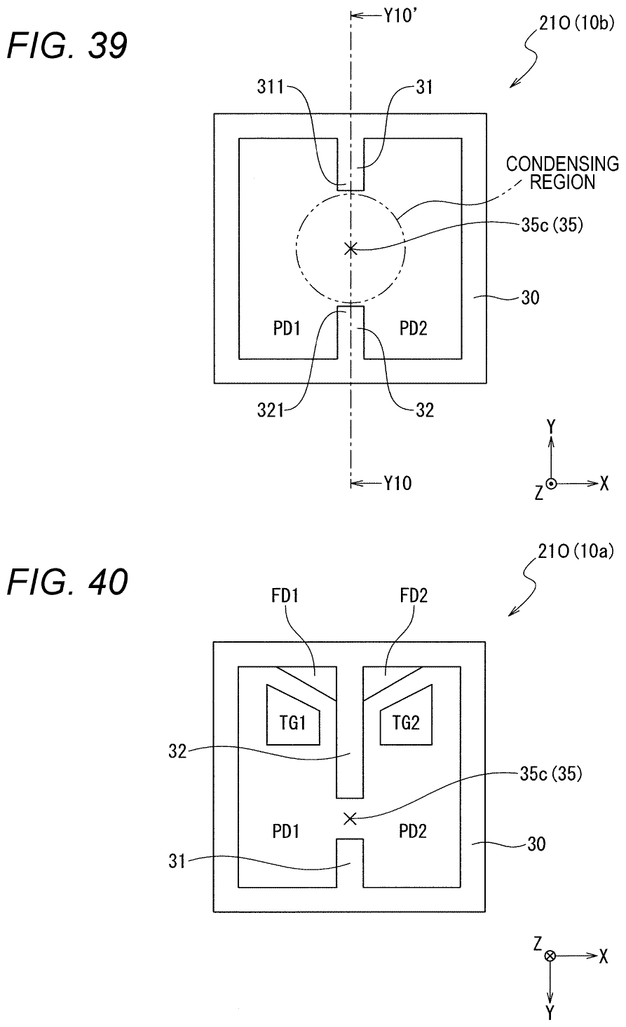

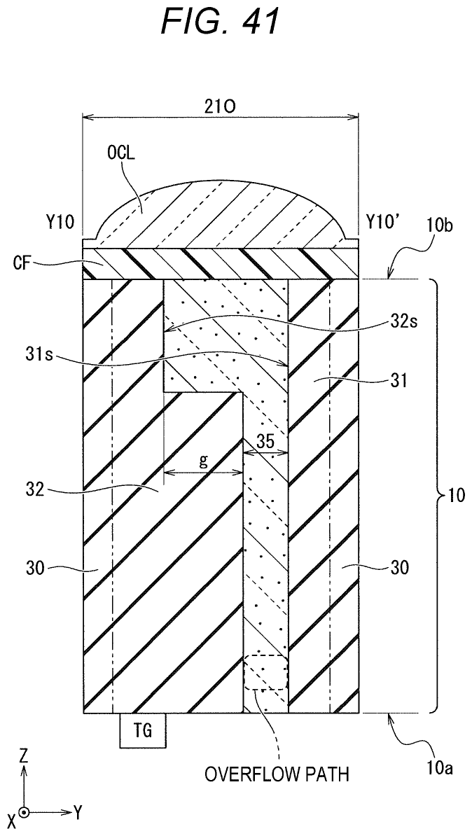

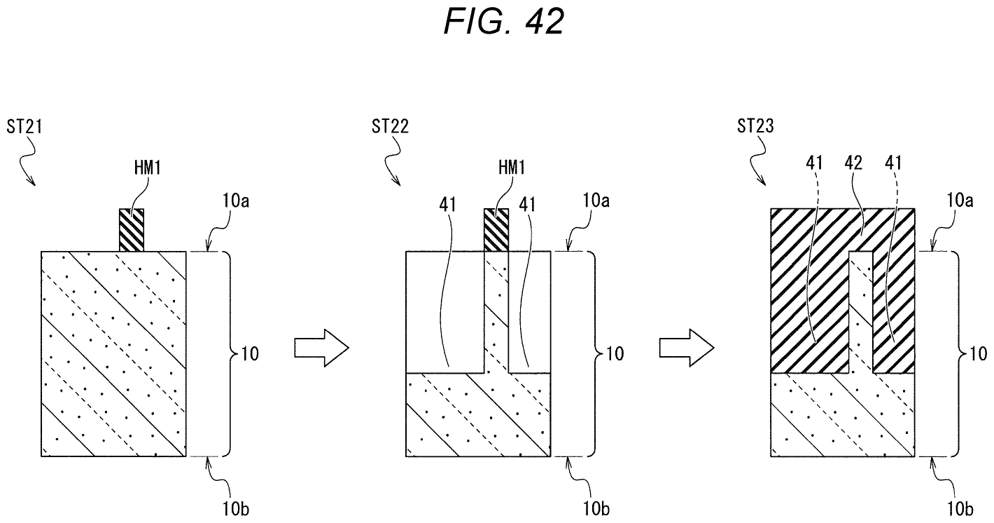

FIGS. 39 and 40 are plan views illustrating a pixel 210 according to a fourth modification of the third embodiment of the present disclosure. FIG. 39 is a diagram of the pixel 210 viewed from the back surface 10b side of the semiconductor substrate 10, and FIG. 40 is a diagram of the pixel 210 viewed from the front surface 10a side of the semiconductor substrate. FIG. 41 is a cross-sectional view illustrating a configuration example of the pixel 210 according to the fourth modification of the third embodiment of the present disclosure. FIG. 41 corresponds to a cross section of the plan view of FIG. 39 taken along line Y10-Y10′. Note that, in FIGS. 39 and 40, illustration of the on-chip lens OCL and the color filter CF is omitted in order to illustrate the inter-pixel isolation portion 30, the first protrusion 31, and the second protrusion 32.

In the pixel 210 illustrated in FIGS. 39 to 41, the side surface 32s of the second protrusion 32 is not tapered but stepped. For example, the side surface 31s of the first protrusion 31 has a linear shape parallel to the thickness direction (for example, the Z-axis direction) of the semiconductor substrate 10, whereas the side surface 32s of the second protrusion 32 has a stepped shape. The width (in FIG. 41, a length in the Y-axis direction) of the gap 35 between the first protrusion 31 and the second protrusion 32 is wide on the side closer to the back surface 10b and narrow on the side (that is, the side close to the front surface 10a) farther from the back surface 10b with a step g interposed therebetween.

Therefore, the central position 35c of the gap 35 is located in the central portion of the pixel 210 on the back surface 10b side, and is located outside the central portion of the pixel 210 on the front surface 10a side.

Even with such a configuration, it is possible to move the overflow path serving as the transfer path of the saturated charge away from the transfer gate TG between the first photodiode PD1 and the second photodiode PD2. The potential of the overflow path can be suppressed from varying by the voltage applied to the transfer gate TG.

Next, the following Methods 1 and 2 will be described as methods of manufacturing the pixel 210 illustrated in FIGS. 39 to 41. The stepped side surface 32s can be formed by the following Methods 1 and 2.

### (4.1) First Method of Fourth Modification

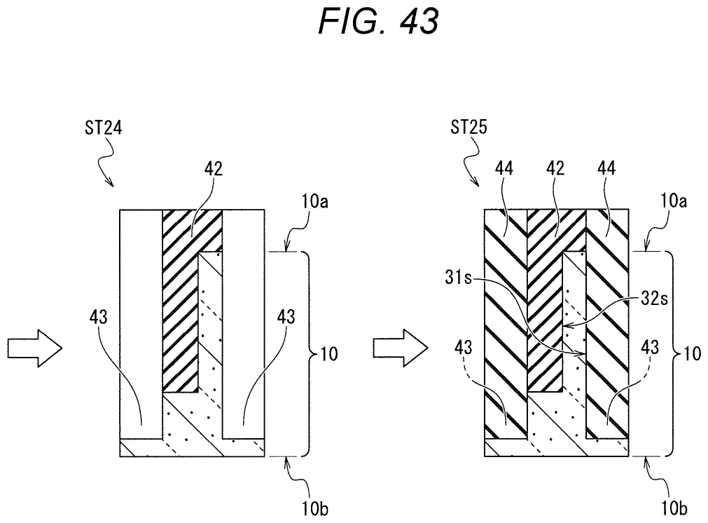

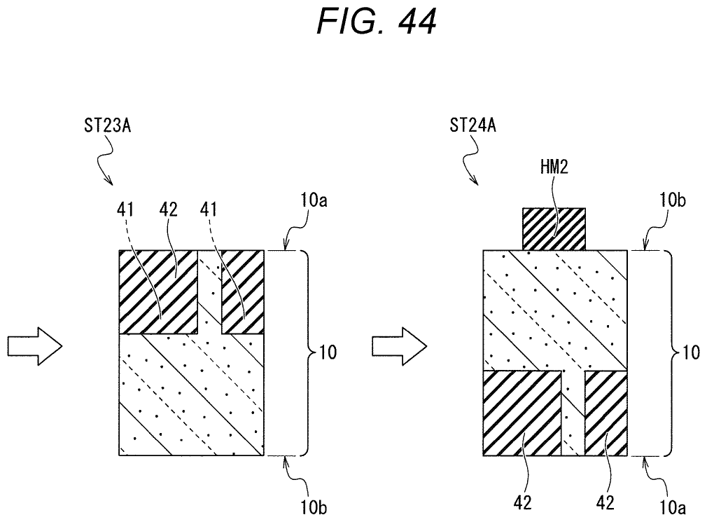

FIGS. 42 and 43 are cross-sectional views illustrating a manufacturing method (first method) of the pixel 210 according to the fourth modification of the third embodiment of the present disclosure in order of steps. As illustrated in step ST21 of FIG. 42, the manufacturing apparatus forms a hard mask HM1 on the front surface 10a of the semiconductor substrate 10. The semiconductor substrate 10 includes, for example, silicon (Si). The hard mask HM1 includes, for example, a silicon oxide film (SiO). The hard mask HM1 has a shape that covers a predetermined region to be the gap 35 (see FIG. 41) on the front surface 10a of the semiconductor substrate 10 and exposes other regions.

Next, as illustrated in step ST22 of FIG. 42, the manufacturing apparatus dry-etches a region exposed from the hard mask HM1 on the front surface 10a side of the semiconductor substrate 10 to form a groove portion 41. After the groove portion 41 is formed, the manufacturing apparatus removes the hard mask HM1 by wet etching or the like.

Next, as illustrated in step ST23 of FIG. 42, the manufacturing apparatus forms a material film 42 other than Si on the front surface 10a side of the semiconductor substrate 10 to fill the groove portion 41. The material film 42 is, for example, SiO, and is formed by a CVD method.

Next, as shown in step ST24 of FIG. 43, the manufacturing apparatus etches the material film 42 to form groove portions 43 in a predetermined region where the inter-pixel isolation portions 30 (see FIG. 41) are to be formed, a predetermined region where the first protrusions 31 (see FIG. 41) are to be formed, and a part of a predetermined region where the second protrusions 32 (see FIG. 41) are to be formed. The etching may be either dry etching or wet etching.

Next, as illustrated in step ST25 of FIG. 43, the manufacturing apparatus forms a material film 44 other than Si on the front surface 10a side of the semiconductor substrate 10 to fill the groove portion 43. The material film 44 is, for example, Sio, and is formed by a CVD method. Through such a process, the pixel 210 having the stepped side surface 32s is completed.

### (4.2) Second Method of Fourth Modification

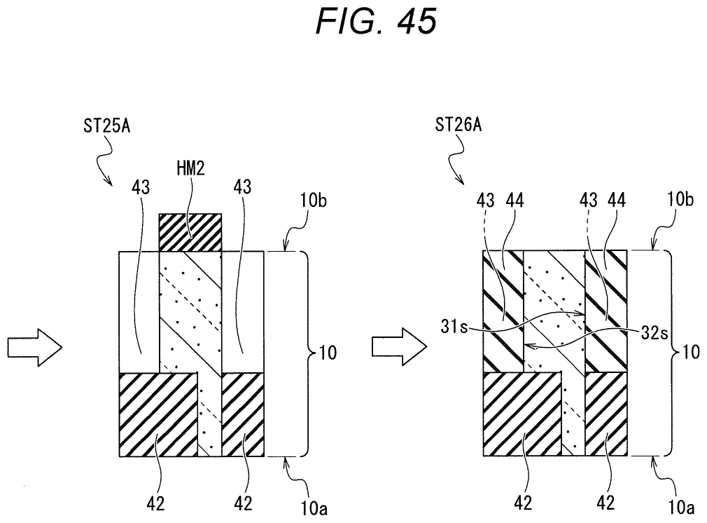

FIGS. 44 and 45 are cross-sectional views illustrating a manufacturing method (second method) of the pixel 210 according to the fourth modification of the third embodiment of the present disclosure in order of steps. In the second method, the steps up to the step of forming the groove portion 41 on the front surface 10a side of the semiconductor substrate 10 and removing the hard mask HM1 (step ST22) are the same as those in the first method. As shown in step ST23A of FIG. 44, after the formation of the groove portion 41, the manufacturing apparatus forms a material film 42 other than Si on the front surface 10a side of the semiconductor substrate 10 to embed the groove portion 41. The material film 42 is, for example, Sio, and is formed by a CVD method. Next, the manufacturing apparatus performs CMP treatment on the material film 42 to expose a predetermined region to be the gap 35 (see FIG. 41) on the front surface 10a side of the semiconductor substrate 10.

Next, as illustrated in step ST24A of FIG. 44, the manufacturing apparatus forms a hard mask HM2 on the back surface 10b of the semiconductor substrate 10. The hard mask HM2 includes, for example, a silicon oxide film (SiO). The hard mask HM2 has a shape that exposes a predetermined region where the inter-pixel isolation portion 30 is to be formed, a predetermined region where the first protrusion 31 is to be formed, and a predetermined region where the second protrusion 32 is to be formed on the back surface 10b of the semiconductor substrate 10 and covers the other regions.

Next, as illustrated in step ST25A of FIG. 45, the manufacturing apparatus dry-etches a region exposed from the hard mask HM2 on the back surface 10b side of the semiconductor substrate 10 to form the groove portion 43. After the groove portion 43 is formed, the manufacturing apparatus removes the hard mask HM2 by wet etching or the like.

Next, as illustrated in step ST26A of FIG. 45, the manufacturing apparatus forms the material film 44 other than Si on the back surface 10b side of the semiconductor substrate 10 to fill the groove portion 43. The material film 44 is, for example, Sio, and is formed by a CVD method. Next, the manufacturing apparatus performs CMP treatment on the material film 44 to expose the back surface 10b of the semiconductor substrate 10. Through such a process, the pixel 210 having the stepped side surface 32s is completed.

### FOURTH EMBODIMENT

In the embodiment of the present disclosure, the first protrusion 31 and the second protrusion 32 may not exist on the back surface 10b of the semiconductor substrate 10, which is the light-receiving surface, but may exist on the front surface 10a of the semiconductor substrate, which is the opposite side of the light-receiving surface.

### Configuration Example

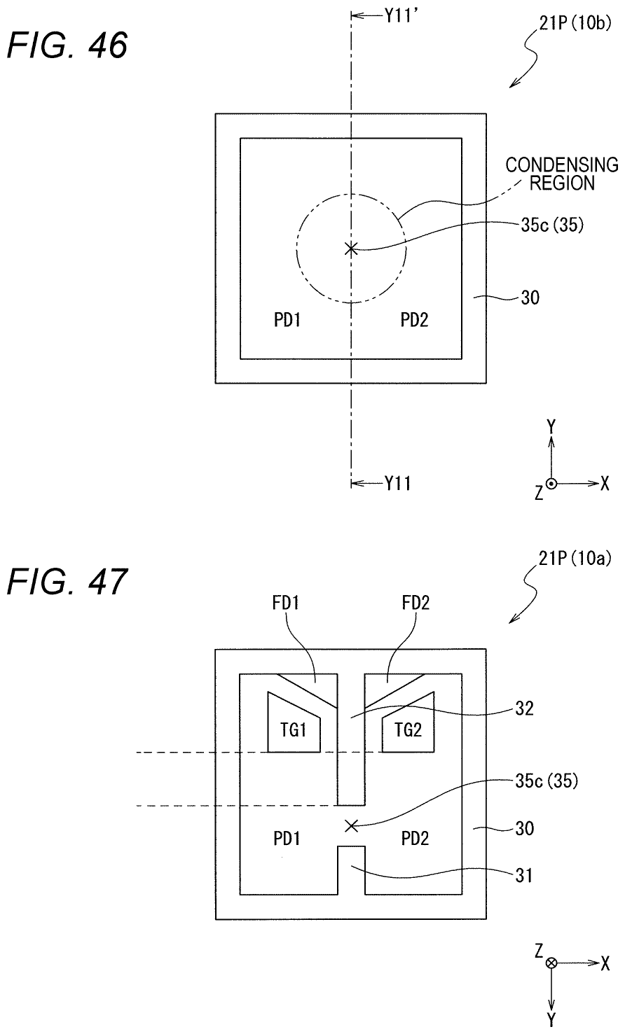

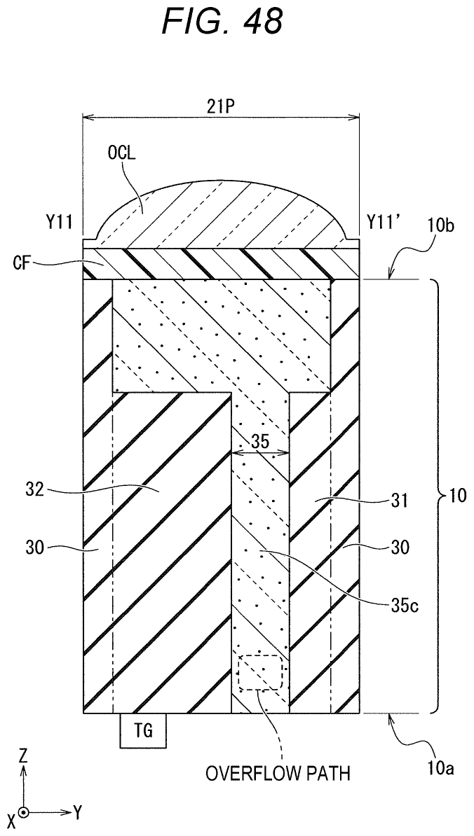

FIGS. 46 and 47 are plan views illustrating configuration examples of a pixel 21P according to a fourth embodiment of the present disclosure. FIG. 46 is a diagram of the pixel 21P viewed from the back surface 10b side of the semiconductor substrate 10, and FIG. 47 is a diagram of the pixel 21P viewed from the front surface 10a side of the semiconductor substrate. FIG. 48 is a cross-sectional view illustrating a configuration example of the pixel 21P according to the fourth embodiment of the present disclosure. FIG. 48 corresponds to a cross section of the plan view of FIG. 46 taken along line Y11-Y11′. Note that, in FIGS. 46 and 47, illustration of the on-chip lens OCL and the color filter CF is omitted in order to illustrate the inter-pixel isolation portion 30, the first protrusion 31, and the second protrusion 32.

As illustrated in FIGS. 46 to 48, in the pixel 21P, the first protrusion 31 and the second protrusion 32 do not exist on the back surface 10b of the semiconductor substrate 10, which is the light-receiving surface, but exist on the front surface 10a of the semiconductor substrate, which is the opposite side of the light-receiving surface. That is, the first protrusion 31 and the second protrusion 32 do not face the back surface 10b of the semiconductor substrate 10. The first protrusion 31 and the second protrusion 32 face the front surface 10a of the semiconductor substrate 10.

According to this, since the first protrusion 31 and the second protrusion 32 do not exist on the back surface 10b of the semiconductor substrate 10 which is the light-receiving surface, scattering and reflection of light by the first protrusion 31 and the second protrusion 32 can be suppressed. The light incident on the pixel 21P can be incident on the first photodiode PD1 and the second photodiode PD2 in a state where reflection and scattering are suppressed.

Furthermore, the overflow path can be moved away from the transfer gate TG. Therefore, the potential of the overflow path can be suppressed from varying due to the voltage applied to the transfer gate TG.

### Manufacturing Method

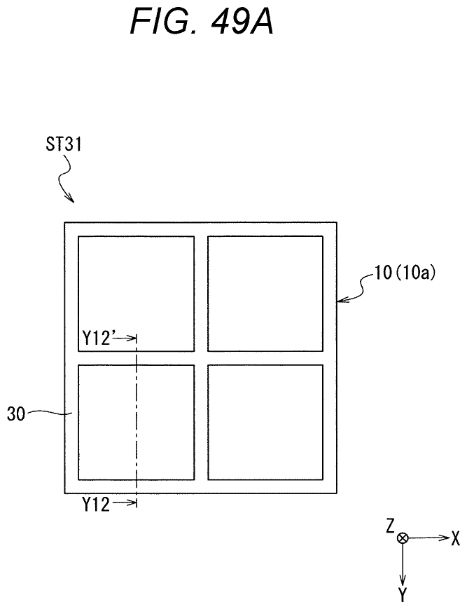

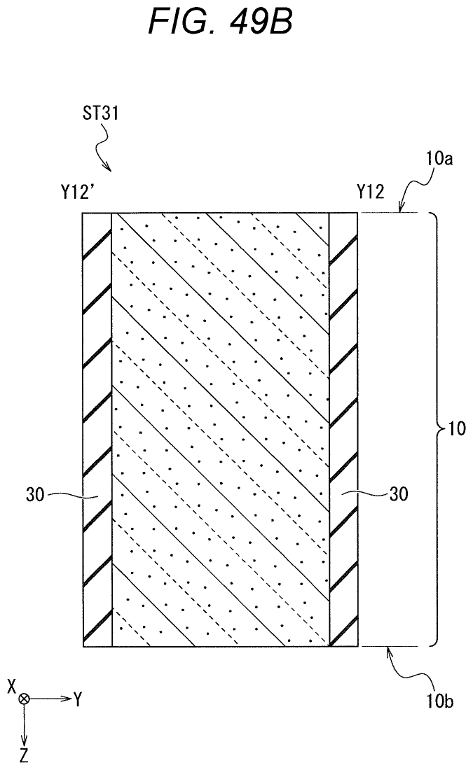

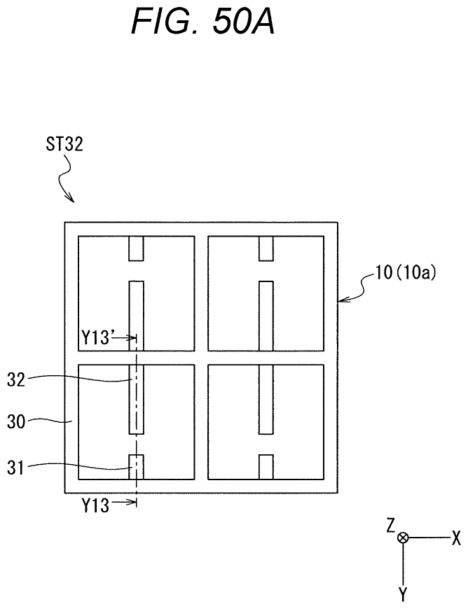

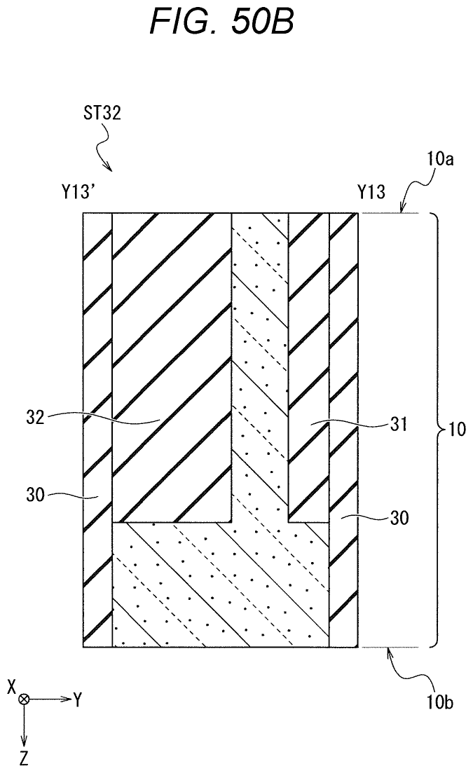

FIG. 49A to 50B are diagrams illustrating a manufacturing method of the pixel 21P according to the fourth embodiment of the present disclosure in order of steps. FIGS. 49A and 50A are plan views, and FIGS. 49B and 50B are cross-sectional views. FIG. 49B corresponds to a cross section of FIG. 49A taken along line Y12-Y12′, and FIG. 50B corresponds to a cross section of FIG. 50A taken along line Y13-Y13′. Note that, in FIGS. 49B and 50B, the front surface 10a of the semiconductor substrate 10 is located on the upper side, and the back surface 10b is located on the lower side.

As illustrated in FIGS. 49A and 49B, the manufacturing apparatus performs patterning and processing on the semiconductor substrate 10 to form the inter-pixel isolation portion 30 on the semiconductor substrate 10 (step ST31). For example, the manufacturing apparatus etches the semiconductor substrate 10 from the front surface 10a side to form a through hole in a predetermined region where the inter-pixel isolation portion 30 is to be formed. This etching is performed by dry etching.

Next, the manufacturing apparatus forms a silicon oxide film (SiO) on the front surface 10a of the semiconductor substrate 10 to fill the through hole provided in the semiconductor substrate 10. Next, the manufacturing apparatus performs CMP treatment on the formed silicon oxide film to remove the silicon oxide film from the region other than the through hole. Therefore, the silicon oxide film is left only in the through hole, and the inter-pixel isolation portion 30 is formed in the semiconductor substrate 10.

Next, as illustrated in FIGS. 50A and 50B, the manufacturing apparatus performs patterning and processing on the semiconductor substrate 10 to form the first protrusion 31 and the second protrusion 32 on the semiconductor substrate 10 (step ST32). For example, the manufacturing apparatus etches the semiconductor substrate 10 from the front surface 10a side to form a through hole in a predetermined region where the first protrusion 31 is to be formed and a predetermined region where the second protrusion 32 is to be formed. This etching is dry etching.

Next, the manufacturing apparatus forms a silicon oxide film (SiO) on the front surface 10a of the semiconductor substrate 10 to fill the through hole provided in the semiconductor substrate 10. Next, the manufacturing apparatus performs CMP treatment on the formed silicon oxide film to remove the silicon oxide film from the region other than the through hole. Therefore, the silicon oxide film is left only in the through hole, and the first protrusion 31 and the second protrusion 32 are formed on the semiconductor substrate 10. Through such steps, the pixel 21P illustrated in FIGS. 46 to 48 is completed.

Note that, in the method of manufacturing the pixel 21P illustrated in FIGS. 49A to 50B, it has been described that the first protrusion 31 and the second protrusion 32 are formed after the inter-pixel isolation portion 30 is formed. However, the method of manufacturing the pixel 21P is not limited thereto. The first protrusion 31 and the second protrusion 32 may be formed first, and then the inter-pixel isolation portion 30 may be formed. Even with such a method, the pixel 21P illustrated in FIGS. 46 to 48 can be manufactured.

### Effect of Fourth Embodiment

As described above, the imaging device 1 according to the fourth embodiment of the present disclosure includes the semiconductor substrate 10 having the back surface 10b on which light is incident and the front surface 10a located on the opposite side of the back surface 10b, the plurality of pixels 21P provided on the semiconductor substrate 10 and performing photoelectric conversion on light, the inter-pixel isolation portion 30 provided on the semiconductor substrate 10 and isolating one pixel 21P and the other pixel 21P adjacent to each other among the plurality of pixels 21P, the first protrusion 31 provided on the semiconductor substrate 10 and protruding from the inter-pixel isolation portion 30 to the inside of the pixel 21P, and the second protrusion 32 provided at the position facing the first protrusion 31 on the semiconductor substrate 10 and protruding from the inter-pixel isolation portion 30 to the inside of the pixel 21P. The first protrusion 31 and the second protrusion 32 do not exist on the back surface 10b but exist on the front surface 10a. A gap 35 exists between the first protrusion 31 and the second protrusion 32.

Accordingly, in the back surface 10b on which light is incident, the light does not hit the first protrusion 31 and the second protrusion 32. Therefore, reflection and scattering of light can be suppressed, and generation of scattered light by light hitting the first protrusion 31 and the second protrusion 32 can be suppressed, so that color mixing between the pixels 21P can be suppressed.

Furthermore, in plan view from the thickness direction (for example, the Z-axis direction) of the semiconductor substrate 10, the central position 35c of the gap 35 in the front surface 10a of the semiconductor substrate 10 is located on the side farther from the transfer gate TG than the central portion of the pixel 21P. The gap 35 functioning as an overflow path is disposed away from the transfer gate TG. Therefore, it is possible to suppress the potential of the overflow path from unintentionally varying due to the influence of the bias of the transfer gate TG.

### Modifications

### (1) First Modification

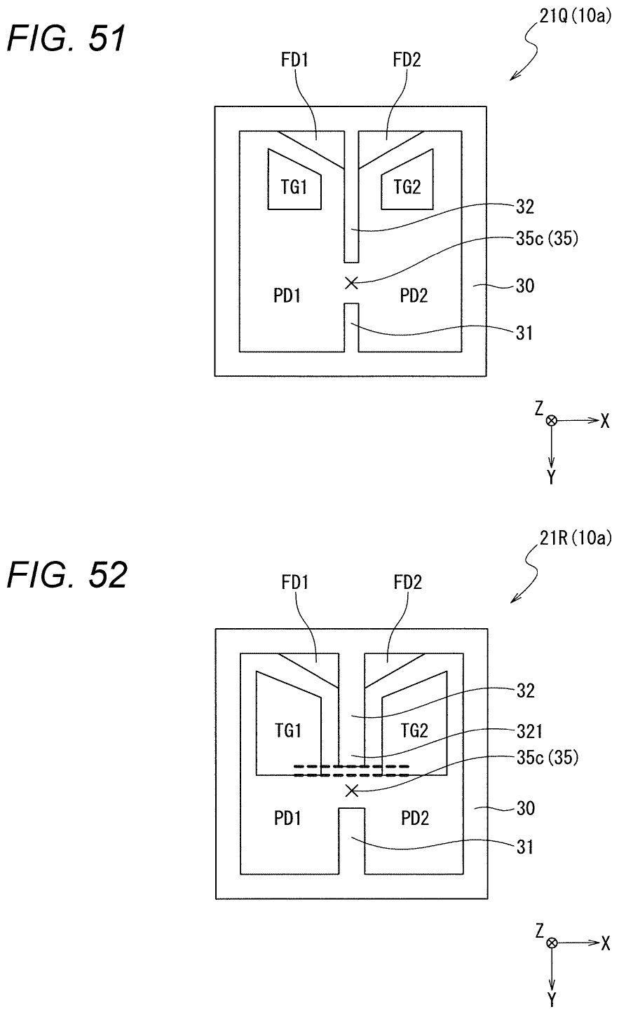

FIG. 51 is a plan view illustrating a pixel 210 according to a first modification of the fourth embodiment of the present disclosure. FIG. 51 is a diagram of the pixel 210 viewed from the front surface 10a side of the semiconductor substrate 10. As illustrated in FIG. 51, in the pixel 210 according to the first modification of the fourth embodiment, the line width (in FIG. 51, the length in the X-axis direction) of the first protrusion 31 and the line width (in FIG. 51, the length in the X-axis direction) of the second protrusion 32 are thinner than the line width of the inter-pixel isolation portion 30 in plan view from the thickness direction of the semiconductor substrate 10. The etching rate tends to be slower for a thinner line width than for a thicker line width. Therefore, in the step of forming the pixel 21Q illustrated in FIG. 51, the inter-pixel isolation portion 30, the first protrusion 31, and the second protrusion 32 can be collectively formed by performing patterning and processing from the front surface 10a side of the semiconductor substrate 10.

### (2) Second Modification

FIG. 52 is a plan view illustrating a pixel 21R according to a second modification of the fourth embodiment of the present disclosure. FIG. 52 is a diagram of the pixel 21R viewed from the front surface 10a side of the semiconductor substrate 10. As illustrated in FIG. 52, in the pixel 21R, the lower sides (that is, the edge side on the pixel center side in the Y-axis direction) of the transfer gates TG1 and TG2 are located below the second tip end portion 321 of the second protrusion 32.

Even with such a configuration, similarly to the fourth embodiment described above, since the first protrusion 31 and the second protrusion 32 do not exist on the back surface 10b of the semiconductor substrate 10 which is the light-receiving surface, scattering and reflection of light by the first protrusion 31 and the second protrusion 32 can be suppressed. The light incident on the pixel 21R can be incident on the first photodiode PD1 and the second photodiode PD2 in a state where reflection and scattering are suppressed.

However, from the viewpoint of the potential of the overflow path, the lower sides (that is, the edge side on the pixel center side in the Y-axis direction) of the transfer gates TG1 and TG2 are preferably located at the same height as the second tip end portion 321 of the second protrusion 32, and are more preferably located above the second tip end portion 321 of the second protrusion 32 as illustrated in FIG. 47. Therefore, since the overflow path can be moved away from the transfer gates TG1 and TG2, it is possible to suppress the potential of the overflow path from unintentionally varying due to the influence of the bias of the transfer gates TG1 and TG2.

### OTHER EMBODIMENTS

As described above, the present disclosure is described according to the embodiments and modifications thereof, but it should not be understood that the description and drawings forming a part of this disclosure limit the present disclosure. Various alternative embodiments, examples, and operation techniques will be apparent to those skilled in the art from this disclosure.

For example, in the above embodiment, the semiconductor substrate 10 may be a multilayer substrate obtained by bonding two or more semiconductor substrates. In the multilayer substrate, the pixel region 12 may be provided on a first semiconductor substrate, and the pixel transistor such as the amplification transistor AMP (see FIG. 1) and various circuits (for example, the vertical drive circuit 13, the column signal processing circuit 14, the horizontal drive circuit 15, the output circuit 16, the control circuit 17, and the like illustrated in FIG. 1) may be provided on a second semiconductor substrate stacked and joined on the first semiconductor substrate via an interlayer insulating film or the like.

Alternatively, in the multilayer substrate, the pixel region 12 may be provided on the first semiconductor substrate, the pixel transistor such as the amplification transistor AMP (see FIG. 1) and a part of the various circuits may be provided on the second semiconductor substrate, and another part of the various circuits may be provided on a third semiconductor substrate stacked and joined on the second semiconductor substrate via an interlayer insulating film or the like.

Furthermore, the configurations of the embodiments of the present disclosure may be obtained by arbitrarily combining the configurations (including modifications) of the first, second, third, and fourth embodiments.

For example, the aspect of the second modification of the fourth embodiment of the present disclosure is applicable not only to the fourth embodiment but also to the third embodiment. That is, in the pixel 21K according to the third embodiment of the present disclosure illustrated in FIG. 30, the lower sides (that is, the edge side on the pixel center side in the Y-axis direction) of the transfer gates TG1 and TG2 may be located below the second tip end portion 321 of the second protrusion 32 as illustrated in FIG. 52. Even with such a configuration, as illustrated in FIG. 29, on the back surface 10b on which light is incident, the gap 35 can be arranged at the central portion of the pixel 21K, and light can be prevented from being applied to the first protrusion 31 and the second protrusion 32 as much as possible. Since it is possible to suppress generation of scattered light by light hitting the first protrusion 31 and the second protrusion 32, it is possible to suppress occurrence of color mixing between the pixels 21K.

As described above, it is needless to say that the present technology includes various embodiments and the like that are not described herein. At least one of various omissions, substitutions, and changes of the components may be made without departing from the gist of the above-described embodiments and modifications. Furthermore, the effect described in the present description is illustrative only; the effect is not limited thereto and there may also be another effect.

Note that the present disclosure can also have the following configurations.

(1) An imaging device including:
a semiconductor substrate having a first surface on which light is incident and a second surface located on an opposite side of the first surface;
a plurality of pixels provided on the semiconductor substrate and configured to perform photoelectric conversion on the light;
an inter-pixel isolation portion provided on the semiconductor substrate and isolating one pixel and another pixel adjacent to each other among the plurality of pixels; and
a first protrusion provided on the semiconductor substrate and protruding from the inter-pixel isolation portion to an inside of the pixel, in which
a first tip end portion of the first protrusion has a first portion located on the first surface side, and
the first portion has a material or structure that absorbs the light as compared with the inter-pixel isolation portion.

(2) The imaging device according to (1), in which the entire first tip end portion has a material or structure that absorbs the light as compared with the inter-pixel isolation portion.

(3) The imaging device according to (1), in which on the first surface, the entire first protrusion has a material or structure that absorbs the light as compared with the inter-pixel isolation portion.

(4) The imaging device according to any one of (1) to (3), in which the inter-pixel isolation portion and the first protrusion are provided so as to penetrate the semiconductor substrate from the first surface to the second surface.

(5) The imaging device according to any one of (1) to (3), in which the inter-pixel isolation portion and the first protrusion are provided from the first surface to a midway position between the first surface and the second surface.

(6) The imaging device according to any one of (1) to (5), in which
a first tip end portion of the first protrusion has a second portion located on the second surface side, and
the second portion is at a position different from the first portion in a thickness direction of the semiconductor substrate.

(7) The imaging device according to any one of (1) to (6), in which
each of the plurality of pixels includes a first photoelectric conversion unit and a second photoelectric conversion unit adjacent to the first photoelectric conversion unit, and
the first protrusion is disposed between the first photoelectric conversion unit and the second photoelectric conversion unit in plan view from a thickness direction of the semiconductor substrate.

(8) The imaging device according to any one of (1) to (7), further including:
a lens body that is provided on the first surface side of the semiconductor substrate and condenses the light on the pixel, in which
the first portion is disposed in the pixel so as to cover a condensing region where the lens body condenses the light.

(9) The imaging device according to any one of (1) to (8), in which a material, which absorbs the light, is a high refractive index material having a refractive index higher than that of the inter-pixel isolation portion or a black material.

(10) The imaging device according to any one of (1) to (8), in which a structure, which absorbs the light, is an uneven structure.

(11) The imaging device according to any one of (1) to (10), in which the first tip end portion has a line width larger than a line width of a portion other than the first tip end portion in the first protrusion in plan view from a thickness direction of the semiconductor substrate.

(12) The imaging device according to any one of (1) to (11), further including:
a second protrusion provided at a position facing the first protrusion in the semiconductor substrate and protruding from the inter-pixel isolation portion to an inside of the pixel, in which
a gap exists between the first protrusion and the second protrusion.

(13) The imaging device according to (12), in which each of the first tip end portion and a second tip end portion of the second protrusion has the first portion.

(14) An imaging device including:
a semiconductor substrate having a first surface on which light is incident and a second surface located on an opposite side of the first surface;
a plurality of pixels provided on the semiconductor substrate and configured to perform photoelectric conversion on the light;
an inter-pixel isolation portion provided on the semiconductor substrate and isolating one pixel and another pixel adjacent to each other among the plurality of pixels;
a first protrusion provided on the semiconductor substrate and protruding from the inter-pixel isolation portion to an inside of the pixel; and
a second protrusion provided at a position facing the first protrusion in the semiconductor substrate and protruding from the inter-pixel isolation portion to an inside of the pixel, in which
a gap exists between the first protrusion and the second protrusion, and
a central position of the gap is different between the first surface and the second surface in a direction in which the first protrusion and the second protrusion face each other.

(15) The imaging device according to (14), further including:
a lens body that is provided on the first surface side of the semiconductor substrate and condenses the light on the pixel, in which
on the first surface, the central position of the gap is located in a condensing region where the lens body condenses the light in the pixel.

(16) The imaging device according to (14) or (15), in which each of the plurality of pixels includes:
a photoelectric conversion unit;
a floating diffusion that converts a charge generated by the photoelectric conversion unit into a voltage signal; and
a transfer transistor that transfers a charge generated by the photoelectric conversion unit to the floating diffusion, and
a central position of the gap on the second surface is located on a side farther from the transfer transistor than a central position of the gap on the first surface in plan view from a thickness direction of the semiconductor substrate.

(17) The imaging device according to any one of (14) to (16), in which one of the first protrusion and the second protrusion has a line width smaller than a line width of another one of the first protrusion and the second protrusion.

(18) An imaging device including:
a semiconductor substrate having a first surface on which light is incident and a second surface located on an opposite side of the first surface;
a plurality of pixels provided on the semiconductor substrate and configured to perform photoelectric conversion on the light;
an inter-pixel isolation portion provided on the semiconductor substrate and isolating one pixel and another pixel adjacent to each other among the plurality of pixels;
a first protrusion provided on the semiconductor substrate and protruding from the inter-pixel isolation portion to an inside of the pixel; and
a second protrusion provided at a position facing the first protrusion in the semiconductor substrate and protruding from the inter-pixel isolation portion to an inside of the pixel, in which
the first protrusion and the second protrusion do not exist on the first surface but exist on the second surface, and a gap exists between the first protrusion and the second protrusion.

(19) The imaging device according to (18), in which each of the plurality of pixels includes:
a photoelectric conversion unit;
a floating diffusion that converts a charge generated by the photoelectric conversion unit into a voltage signal; and
a transfer transistor that transfers a charge generated by the photoelectric conversion unit to the floating diffusion, and
a central position of the gap on the second surface is located on a side farther from the transfer transistor than a central portion of the pixel in plan view from a thickness direction of the semiconductor substrate.

### REFERENCE SIGNS LIST

1 Imaging device
10 Semiconductor substrate
10a Front surface
10b Back surface
12 Pixel region
13 Vertical drive circuit
14 Column signal processing circuit
15 Horizontal drive circuit
16 Output circuit
17 Control circuit
20 Read circuit
21, 21A to 21R Pixel
22 Horizontal signal line
23 Vertical signal line
24 Data output signal line
30 Inter-pixel isolation portion
31 First protrusion
31b, 311b, 321b, 331b, 341b Back surface side portion
31s, 32s Side surface
32 Second protrusion
32b, 311a, 321a Front surface side portion
33 Third protrusion
34 Fourth protrusion
35 Gap
35c Center position
36 Intermediate second layer
37 Polycrystalline silicon film
38 Silicon nitride film
39 Silicon oxide film
41, 43 Groove portion
42, 44 Material film
47 Pillar
110 Light absorbing structure
135 Oxide film
136 Intermediate second layer
137 Intermediate first layer
137a Recess
138 Si layer
210 Light absorbing structure
212 Semiconductor layer
245 Uneven structure
247 Pillar
311, 311′ First tip end portion
321, 321′ Second tip end portion
331, 341 Tip end portion
AMP Amplification transistor
CF Color filter
FD, FD1, FD2 Floating diffusion
g Step
h1 Opening
h2, h3, h4 Through hole
HM1, HM2 Hard mask
OCL On-chip lens
PD Photodiode
PD1 First photodiode
PD2 Second photodiode
PD3 Third photodiode
PD4 Fourth photodiode
RST Reset transistor
SEL Selection transistor
TG, TG1, TG2 Transfer gate
TR, TR1, TR2 Transfer transistor
V1, V2 Volume
Vdd Power line

1. An imaging device comprising:
a semiconductor substrate having a first surface on which light is incident and a second surface located on an opposite side of the first surface;
a plurality of pixels provided on the semiconductor substrate and configured to perform photoelectric conversion on the light;
an inter-pixel isolation portion provided on the semiconductor substrate and isolating one pixel and another pixel adjacent to each other among the plurality of pixels; and
a first protrusion provided on the semiconductor substrate and protruding from the inter-pixel isolation portion to an inside of the pixel, wherein
a first tip end portion of the first protrusion has a first portion located on the first surface side, and
the first portion has a material or structure that absorbs the light as compared with the inter-pixel isolation portion.

2. The imaging device according to claim 1, wherein the entire first tip end portion has a material or structure that absorbs the light as compared with the inter-pixel isolation portion.

3. The imaging device according to claim 1, wherein on the first surface, the entire first protrusion has a material or structure that absorbs the light as compared with the inter-pixel isolation portion.

4. The imaging device according to claim 1, wherein the inter-pixel isolation portion and the first protrusion are provided so as to penetrate the semiconductor substrate from the first surface to the second surface.

5. The imaging device according to claim 1, wherein the inter-pixel isolation portion and the first protrusion are provided from the first surface to a midway position between the first surface and the second surface.

6. The imaging device according to claim 1, wherein a first tip end portion of the first protrusion has a second portion located on the second surface side, and the second portion is at a position different from the first portion in a thickness direction of the semiconductor substrate.

7. The imaging device according to claim 1, wherein
each of the plurality of pixels includes a first photoelectric conversion unit and a second photoelectric conversion unit adjacent to the first photoelectric conversion unit, and
the first protrusion is disposed between the first photoelectric conversion unit and the second photoelectric conversion unit in plan view from a thickness direction of the semiconductor substrate.

8. The imaging device according to claim 1, further comprising:
a lens body that is provided on the first surface side of the semiconductor substrate and condenses the light on the pixel, wherein
the first portion is disposed in the pixel so as to cover a condensing region where the lens body condenses the light.

9. The imaging device according to claim 1, wherein a material, which absorbs the light, is a high refractive index material having a refractive index higher than that of the inter-pixel isolation portion or a black material.

10. The imaging device according to claim 1, wherein a structure, which absorbs the light, is an uneven structure.

11. The imaging device according to claim 1, wherein the first tip end portion has a line width larger than a line width of a portion other than the first tip end portion in the first protrusion in plan view from a thickness direction of the semiconductor substrate.

12. The imaging device according to claim 1, further comprising:
a second protrusion provided at a position facing the first protrusion in the semiconductor substrate and protruding from the inter-pixel isolation portion to an inside of the pixel, wherein
a gap exists between the first protrusion and the second protrusion.

13. The imaging device according to claim 12, wherein each of the first tip end portion and a second tip end portion of the second protrusion has the first portion.

14. An imaging device comprising:
a semiconductor substrate having a first surface on which light is incident and a second surface located on an opposite side of the first surface;
a plurality of pixels provided on the semiconductor substrate and configured to perform photoelectric conversion on the light;
an inter-pixel isolation portion provided on the semiconductor substrate and isolating one pixel and another pixel adjacent to each other among the plurality of pixels;
a first protrusion provided on the semiconductor substrate and protruding from the inter-pixel isolation portion to an inside of the pixel; and
a second protrusion provided at a position facing the first protrusion in the semiconductor substrate and protruding from the inter-pixel isolation portion to an inside of the pixel, wherein
a gap exists between the first protrusion and the second protrusion, and
a central position of the gap is different between the first surface and the second surface in a direction in which the first protrusion and the second protrusion face each other.

15. The imaging device according to claim 14, further comprising:
a lens body that is provided on the first surface side of the semiconductor substrate and condenses the light on the pixel, wherein on the first surface, the central position of the gap is located in a condensing region where the lens body condenses the light in the pixel.

16. The imaging device according to claim 14, wherein each of the plurality of pixels includes:
a photoelectric conversion unit;
a floating diffusion that converts a charge generated by the photoelectric conversion unit into a voltage signal; and
a transfer transistor that transfers a charge generated by the photoelectric conversion unit to the floating diffusion, and a central position of the gap on the second surface is located on a side farther from the transfer transistor than a central position of the gap on the first surface in plan view from a thickness direction of the semiconductor substrate.

17. The imaging device according to claim 14, wherein one of the first protrusion and the second protrusion has a line width smaller than a line width of another one of the first protrusion and the second protrusion.

18. An imaging device comprising:
a semiconductor substrate having a first surface on which light is incident and a second surface located on an opposite side of the first surface;
a plurality of pixels provided on the semiconductor substrate and configured to perform photoelectric conversion on the light;
an inter-pixel isolation portion provided on the semiconductor substrate and isolating one pixel and another pixel adjacent to each other among the plurality of pixels;
a first protrusion provided on the semiconductor substrate and protruding from the inter-pixel isolation portion to an inside of the pixel; and
a second protrusion provided at a position facing the first protrusion in the semiconductor substrate and protruding from the inter-pixel isolation portion to an inside of the pixel, wherein
the first protrusion and the second protrusion do not exist on the first surface but exist on the second surface, and
a gap exists between the first protrusion and the second protrusion.

19. The imaging device according to claim 18, wherein each of the plurality of pixels includes:
a photoelectric conversion unit;
a floating diffusion that converts a charge generated by the photoelectric conversion unit into a voltage signal; and
a transfer transistor that transfers a charge generated by the photoelectric conversion unit to the floating diffusion, and
a central position of the gap on the second surface is located on a side farther from the transfer transistor than a central portion of the pixel in plan view from a thickness direction of the semiconductor substrate.
